(19) United States
(12) Patent Application Publication
(10) Pub. No.: US 2007/0279113 A1
(43) Pub. Date: Dec. 6, 2007

(54) Dll Circuit

(76) Inventors: Kengo Maeda, Nara (JP); Akira Tanigawa, Kyoto (JP); Masuji Nishiyama, Osaka (JP); Shoichi Ohori, Nara (JP); Makoto Hirano, Hyogo (JP); Hiroshi Takashima, Kyoto (JP); Shinji Matoba, Nara (JP); Masamichi Asano, Kyoto (JP)

Correspondence Address: MORRISON & FOERSTER LLP, 755 PAGE MILL RD, PALO ALTO, CA, 94304-1018, US

(21) Appl. No.: 10/590,225

(22) PCT Filed: Feb. 9, 2005
(86) PCT No.: PCT/JP05/01896

§ 371 Date: May 4, 2007

(30) Foreign Application Priority Data
Feb. 27, 2004 (JP) 2004-053774

(51) Int. Cl. H03L 7/06

(52) U.S. Cl. 327/158

(57) ABSTRACT

A DLL circuit comprises a dummy delay corresponding to an internal clock delay from an external clock, a variable delay addition circuit having a coarse and fine delay circuits adjusting delay amount according to a delay amount adjustment signal, and a phase comparison circuit comparing phases of the internal clock and a delay clock input via the variable delay addition circuit and the dummy delay and outputting the delay amount adjustment signal to the variable delay addition circuit. At the start of burst, a first signal set at a logic “1” during 1 clock cycle of the internal clock is input to the variable delay addition circuit via the dummy delay, and duration time of the logic “1” of the first signal is detected until 1 clock cycle of the internal clock is completed and delay amount of the variable delay addition circuit is initialized by setting one of the coarse delay circuit based on the duration time.

### CROSS-REFERENCE TO RELATED APPLICATIONS

This application is a National Phase filing under 35 U.S.C. § 371 of International Application No. PCT/JP2005/001896 filed on Feb. 9, 2005, and which claims priority to Japanese Patent Application No. 2004-053774 filed on Feb. 27, 2004.

### TECHNICAL FIELD

The present invention relates to a DLL (Delay Locked Loop) circuit useful in a semiconductor memory, for example, a flash memory.

### BACKGROUND ART

In recent years, demand for the flash memory as a nonvolatile memory has rapidly increased. Under such situation, read speed has also increased and operation at clock frequencies exceeding 100 MHz needs to be practicable. Therefore, in the flash memory, a mechanism to cancel delay in internal clock becomes essential. So far, although not for the flash memory, various DLL (Delay Locked Loop) circuits have been provided or proposed (refer to, for example, Patent document 1).

[Patent document 1] Unexamined Patent Publication No. 2001-326563

### DISCLOSURE OF INVENTION

### Problems to be Solved by the Invention

A need for a DLL circuit will be described below with reference to FIG. 17. FIG. 17 is a view for showing the need for the DLL circuit.

A DLL circuit of the present invention (described later) targets burst synchronous operation at a high speed clock (for example, 133 MHz). However, as shown in FIG. 17A, in the case of the external clock of 133 MHz and cycle T of 7.5 ns, due to internal clock delay (about 3 to 4 ns) and DQ buffer delay (about 5 ns), timing of DQ output gets late and thus, setup time (0.5 ns) of specifications cannot be ensured.

Thus, by adopting the DLL circuit, the internal clock delay and the like are cancelled to ensure the setup time of DQ output with respect to the external clock. In this DLL circuit, as shown in FIG. 17B, an internal clock delayed in a chip is further delayed until the next external clock, thereby canceling the clock internal delay.

To delay the internal clock until an edge of the next external clock, a delay element of “cycle T-internal clock delay” (DLL delay) may be provided. However, the delay element can be used only in the case where the cycle T is constant (internal clock delay+DLL delay=clock cycle T). Therefore, to address various cycles, DLL delay may be controlled so as to become larger as the cycle is larger and to become smaller as the cycle is smaller. For this reason, two circuit, that is, a circuit for determining the clock cycle (phase comparison circuit) and a delay circuit capable of varying delay amount according to determination by the phase comparison circuit (variable delay addition circuit) are prepared to generate the state “internal clock delay+DLL delay=1 clock cycle T”.

To achieve this, a conventional DLL circuit will be described with reference to FIG. 18. FIG. 18 is a view showing a conventional example of the DLL circuit.

An internal clock (internal CLK) given to a DLL circuit 1000 in FIG. 18 is input at a later timing than an external clock (internal clock delay Δt represented by a reference numeral 1001). When the clock is used as it is, DQ timing is delayed by the internal clock delay (Δt) and thus, setup in the outside cannot be ensured.

Accordingly, in the DLL circuit 1000, by further delaying the delayed clock to have the same phase as the external clock, the internal clock delay is cancelled. To address various cycles, the DLL circuit 1000 uses a variable delay addition circuit 1004 for the internal clock delay. In the state where a dummy delay 1002 equivalent to the internal clock is added, a phase comparison circuit 1003 compares the clock with the original internal clock in phase and the delay amount in the variable delay addition circuit 1004 is adjusted so that both the clocks may have the same phase (dummy delay+variable delay=1 cycle). At the time when both the clocks have the same phase, the internal delay (=dummy delay) of the DLL clock from which the dummy delay (Δt′) is subtracted is cancelled and the DLL clock has the same phase as the external clock. FIG. 19 is a timing chart.

In FIG. 19, the variable delay addition circuit 1004 adjusts delay amount so that the phase of the delay clock corresponds to the phase of the internal clock (dummy delay+DLL delay=1 clock cycle). At the time when both the phases correspond to each other, the relationship “dummy delay (corresponding to the internal clock delay)+DLL delay=cycle T” is met and at the timing when the dummy delay is subtracted from the delay clock, the DLL clock has the same phase as the external clock.

In the above-mentioned DLL circuit, since an external clock frequency is basically unknown, phase comparison and correction need to be repeated. Thus, time for phase correction is several ten to several hundred cycles.

However, in the current flash memory, DQ needs to be output in a few clocks from start of synchronous reading and the conventional DLL circuits such as the above-mentioned DLL circuit cannot meet the requirement. Alternatively, to meet the requirement by the current flash memory, it can be considered to input the external clock even during standby and perform phase correction in the DLL circuit at all times. However, this approach leads to a problem of uselessly increasing power consumption.

Therefore, an object of the present invention is to provide a DLL circuit capable of generating a corrected DLL clock in a few clocks from standby state.

### Means for Solving the Problem

A DLL circuit as stated in claim 1 includes: a dummy delay corresponding to an internal clock delay with respect to an external clock; a variable delay addition circuit having a coarse delay circuit and a fine delay circuit, for adjusting delay amount according to a delay amount adjustment signal; and a phase comparison circuit for comparing a phase of the internal clock with a phase of a delay clock input via the variable delay addition circuit and the dummy delay and outputting the delay amount adjustment signal to the variable delay addition circuit, wherein the DLL circuit has, as an initialization mode at the time of burst start, a means for inputting a first signal set at a logic “1” during 1 clock cycle of the internal clock to the variable delay addition circuit via the dummy delay and a means for detecting duration time of the logic “1” of the first signal input by the variable delay addition circuit through the dummy delay until the end of the 1 clock cycle of the internal clock and setting an initial value of delay amount of the variable delay addition circuit by setting the delay amount of the coarse delay circuit in the variable delay addition circuit based on the duration time; and as a lock mode after initial setting of the delay amount in the variable delay addition circuit, has a clock output means for delaying the internal clock by the coarse delay circuit and the fine delay circuit in the variable delay addition circuit and generating an output clock that synchronizes with the external clock with a delay of 1 clock while correcting the delay amount of the coarse delay circuit and the fine delay circuit in the variable delay addition circuit according to the delay amount adjustment signal output from the phase comparison circuit.

A DLL circuit as stated in claim 2 includes: a dummy delay corresponding to an internal clock delay with respect to an external clock; a variable delay addition circuit having a coarse delay circuit and a fine delay circuit, for adjusting delay amount according to a delay amount adjustment signal; and a phase comparison circuit for comparing a phase of the internal clock with a phase of a delay clock input via the variable delay addition circuit and the dummy delay and outputting the delay amount adjustment signal to the variable delay addition circuit, wherein the DLL circuit has, as an initialization mode at the time of burst start, a means for inputting a first signal set at a logic “1” during 1 clock cycle of the internal clock to the variable delay addition circuit via the dummy delay and a means for detecting duration time of the logic “1” of the first signal input by the variable delay addition circuit through the dummy delay until the end of the 1 clock cycle of the internal clock and setting an initial value of delay amount of the variable delay addition circuit by setting the delay amount of the coarse delay circuit in the variable delay addition circuit based on the duration time; and as a lock mode after initial setting of the delay amount in the variable delay addition circuit, has a clock output means for delaying the internal clock by the coarse delay circuit and the fine delay circuit in the variable delay addition circuit and generating an output clock that synchronizes with the external clock with a delay of 1 clock while correcting the delay amount of the coarse delay circuit and the fine delay circuit in the variable delay addition circuit according to the delay amount adjustment signal output from the phase comparison circuit, the coarse delay circuit operates as the variable delay addition circuit and a means for storing setting of the initial value in the initialization mode and operates as a coarse variable delay addition circuit having coarse unit delay amount in the lock mode, and the fine delay circuit operates as a fine variable delay addition circuit adding delay amount for complementing the unit delay amount of the coarse delay circuit by having fine unit delay amount in the lock mode.

A DLL circuit as stated in claim 3 comprises a means for preventing delay from being added to the delay clock in the fine delay circuit in the variable delay circuit, when the phase of the delay clock obtained by adding predetermined threshold delay amount to the internal clock lags behind the internal clock, as a determination result of the phase comparison circuit in the lock mode.

In a DLL circuit as stated in claim 4, a delay element in the coarse delay circuit and the fine delay circuit which form the variable delay addition circuit is formed of an inverter circuit and a circuit having inverse characteristics to the inverter circuit in terms of power supply voltage.

A variable delay addition circuit as stated in claim 5 forms a DLL circuit including: a dummy delay corresponding to an internal clock delay with respect to an external clock; a variable delay addition circuit having a coarse delay circuit and a fine delay circuit, for adjusting delay amount according to a delay amount adjustment signal; and a phase comparison circuit for comparing a phase of the internal clock with a phase of a delay clock input via the variable delay addition circuit and the dummy delay, outputting the delay amount adjustment signal to the variable delay addition circuit, and having a logic circuit for detecting that the delay amount of the coarse delay circuit and the fine delay circuit is set to be minimum by the delay amount setting signal output from the coarse delay circuit and the fine delay circuit, wherein the fine delay circuit includes: a register that stores a signal output from the phase comparison circuit for bypassing the fine delay circuit; and a switching means for bypassing the delay addition unit in the fine delay circuit in response to the output of the register, and the delay addition unit in the fine delay circuit is bypassed and the delay is prevented from being added in the fine delay circuit, when the delay amounts of both the coarse delay circuit and the fine delay circuit are set to be minimum and the phase of the delay clock lags behind the internal clock.

### EFFECT OF THE INVENTION

According to claim 1, at the time of burst start, the first signal output during 1 clock cycle of the internal clock is input to the variable delay addition circuit through the dummy delay. The variable delay addition circuit measures duration time of the logic “1” of the first signal until the end of 1 clock cycle and initializes delay amount of the variable delay addition circuit by setting delay amount of the coarse delay circuit based on the duration time. Thereby, at start of the operation, the phase can be adjusted in an extremely short time.

According to claim 2, at the time of burst start, the first signal output during 1 clock cycle of the internal clock is input to the variable delay addition circuit through the dummy delay. The variable delay addition circuit measures duration time of the logic “1” of the first signal until the end of 1 clock cycle and initializes delay amount of the variable delay addition circuit by setting delay amount of the coarse delay circuit based on the duration time. Thereby, at start of the operation, the phase can be adjusted in an extremely short time.

In the lock mode, since the unit delay amount of the coarse delay circuit is complemented in the coarse delay circuit, adjustment range of the delay amount can be made smaller.

According to claim 3, though both the delay amount of the coarse delay circuit and the delay amount of the fine delay circuit are set to be minimum, the case where the phase of the delay clock is too delayed can be advantageously addressed. That is, the range of the delay amount which can be added in the variable delay addition circuit can be increased.

According to claim 4, the delay element in the variable delay addition circuit is formed of the inverter circuit and the circuit having inverse characteristics to the inverter circuit in terms of power supply voltage, variations in the delay amount due to variations in power supply voltage can be suppressed.

According to claim 5, though both the delay amount of the coarse delay circuit and the delay amount of the fine delay circuit are set to be minimum, the case where the phase of the delay clock is too delayed can be advantageously addressed. That is, the range of the delay amount which can be added in the variable delay addition circuit can be increased.

### BRIEF DESCRIPTION OF DRAWINGS

FIG. 1 is a view showing a configuration example of a semiconductor memory in accordance with an embodiment of the present invention (synchronous read system).

FIG. 2 is a schematic configuration view of the DLL circuit in FIG. 1.

FIG. 3 is a timing chart for describing operations of the DLL circuit in FIG. 2.

FIG. 4 is a circuit diagram showing configuration of a control circuit in FIG. 2.

FIG. 5 is a circuit diagram showing configuration of a control circuit in FIG. 2.

FIG. 6 is a circuit diagram showing configuration of a falling one-shot pulse circuit in FIG. 4.

FIG. 7 is a circuit diagram showing configuration of a dummy delay circuit in FIG. 2.

FIG. 8 is a view showing configuration of a fine adjustment circuit in FIG. 7.

FIG. 9 is a circuit diagram showing configuration of a phase comparison circuit in FIG. 2.

FIG. 10 is a view showing an example of the phase comparison circuit in FIG. 9.

FIG. 11 is a circuit diagram showing configuration of a coarse delay circuit in FIG. 2.

FIG. 12 is a circuit diagram showing configuration of a coarse delay register circuit in FIG. 11.

FIG. 13 is a view of an example of a delay cell for reducing variation in delay time with respect to voltage.

FIG. 14 is a circuit diagram showing configuration of a fine delay circuit in FIG. 2.

FIG. 15 a circuit diagram showing configuration of a fine delay circuit in FIG. 14.

FIG. 16 is a circuit diagram showing configuration of a fine register circuit in FIG. 14.

FIG. 17 is a view for describing a need for a DLL circuit.

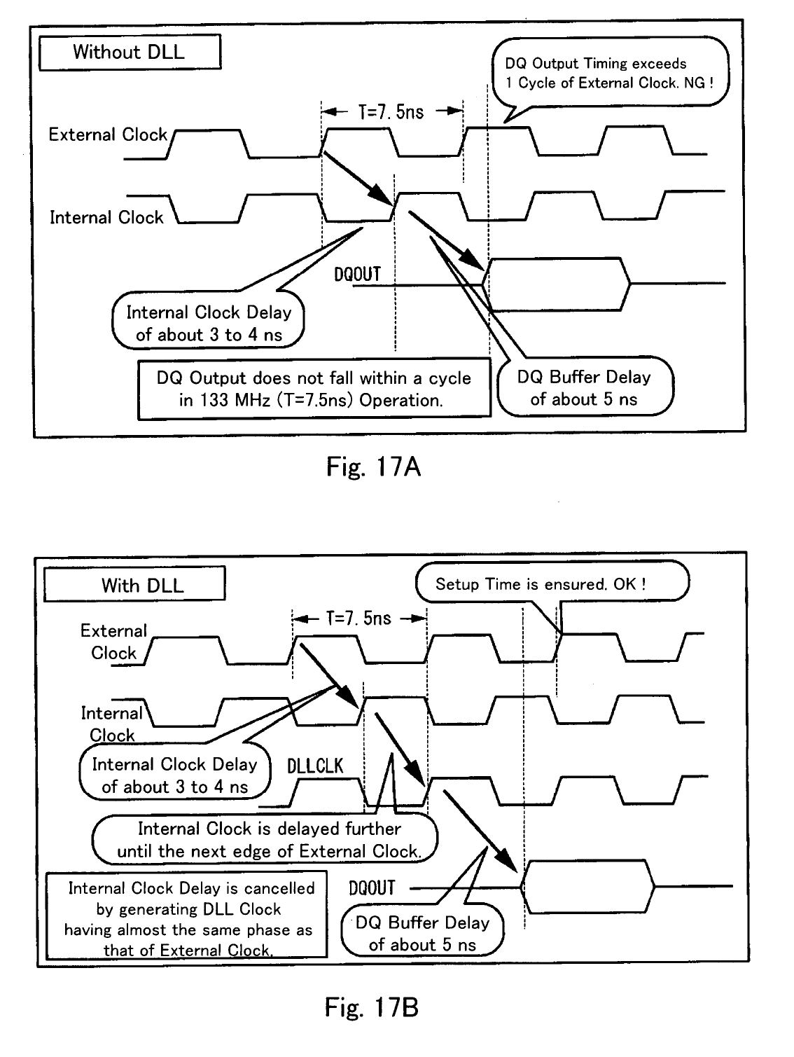

FIG. 18 is a view showing a conventional example of the DLL circuit.

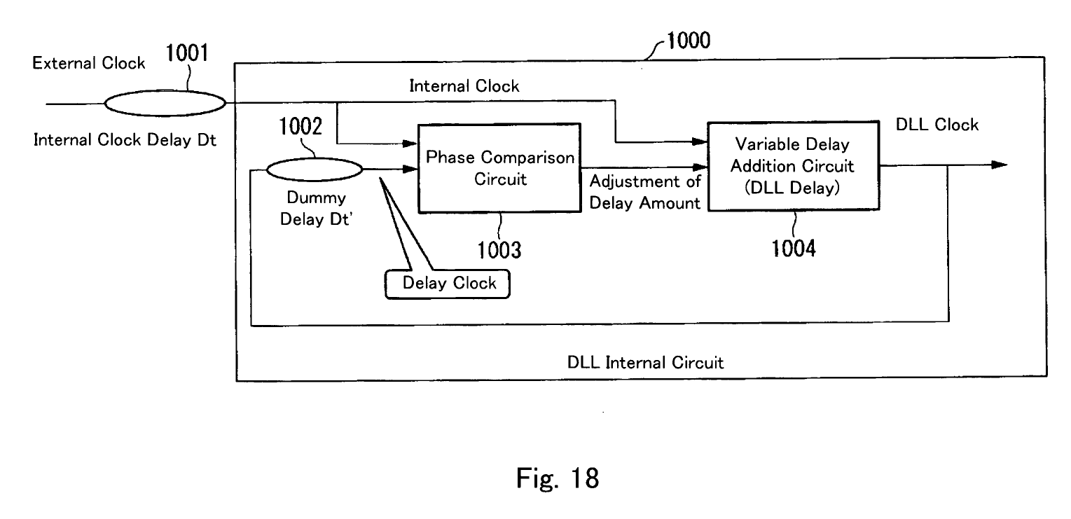

FIG. 19 is a timing chart for describing operations of the DLL circuit in FIG. 18.

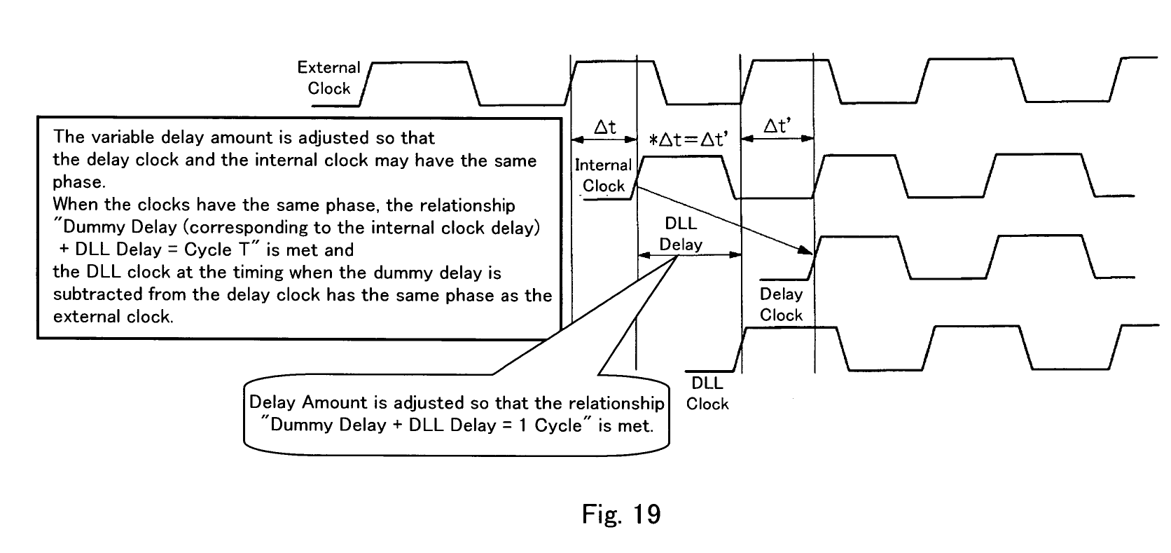

### EXPLANATION OF REFERENCES

6: DLL Circuit
100: Control Circuit
200: Dummy Delay Circuit
300: Phase Comparison Circuit
400: Coarse Delay Circuit
500: Fine Delay Circuit

### BEST MODE FOR CARRYING OUT THE INVENTION

A best embodiment of the present invention will be described below with reference to figures.

<<Semiconductor Memory Circuit>>

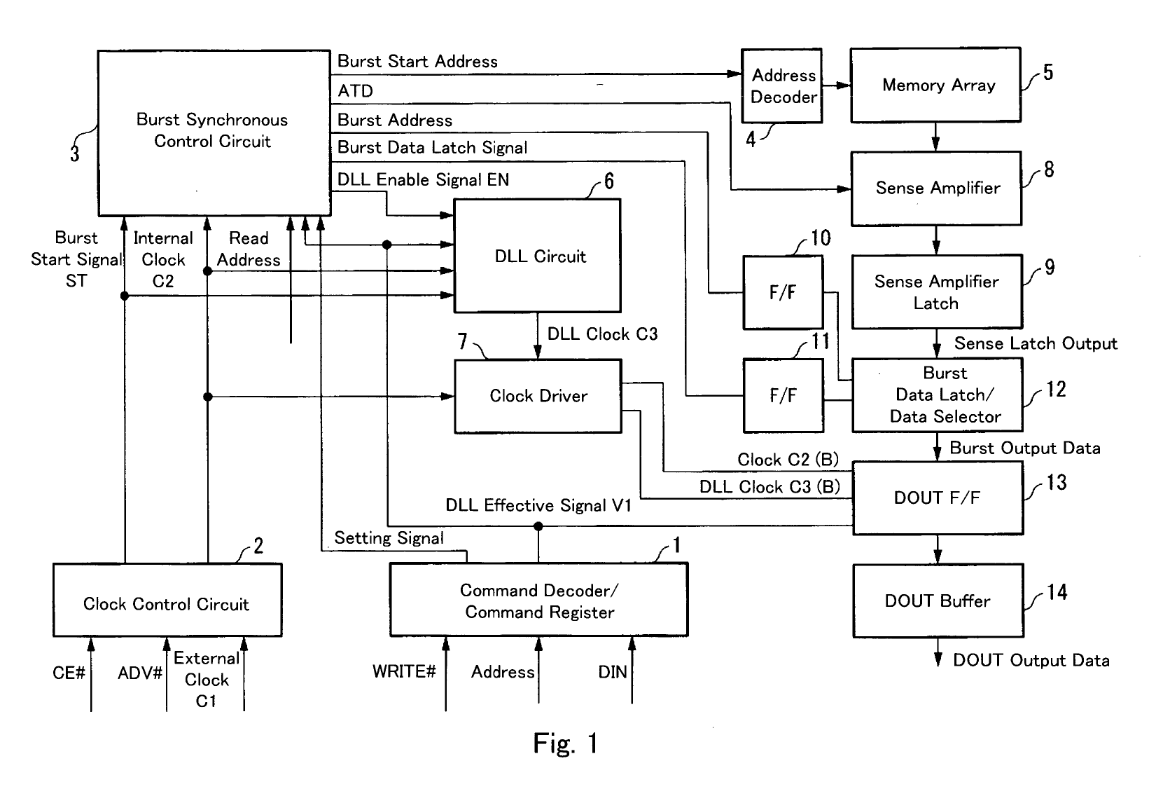

FIG. 1 is a view showing a configuration example of a semiconductor memory using a DLL circuit in accordance with the embodiment of the present invention (synchronous read system) and the semiconductor memory is a flash memory. “#” added to the end of each signal indicates that the signal becomes effective in negative logic “L”.

In FIG. 1, a command decoder/command register 1 decodes an address and DIN, determines a command and stores a determination result according to a command write signal WRITE# in the resister. Furthermore, the command decoder/command register 1 sets a type of burst mode, clock latency and use/non-use of DLL. A DLL effective signal (a signal representing use/non-use of DLL) V1 based on the input user command is output to a burst synchronous control circuit 3, a DLL circuit 6 and a DOUT flip flop (DOUT F/F) 13. A setting signal (a signal representing the type of burst mode and clock latency) based on the input user command is output to the burst synchronous control circuit 3. The address is a command designation address and DIN is command designation data.

Based on a chip enable signal CE# and an address effective signal (a signal representing that the input address is an effective address at the time of reading) ADV#, a clock control circuit 2 generates a burst start signal (a signal for starting burst reading) ST and outputs the signal to the burst synchronous control circuit 3 and the DLL circuit 6. The clock control circuit 2 further generates an internal clock C2 from an external clock C1 via an input buffer and feeds the clock C2 to the burst synchronous control circuit 3, the DLL circuit 6 and a clock driver 7.

The burst synchronous control circuit 3 receives an input of a read address (an address for reading) at burst synchronous reading, generates a burst address, controls a sense amplifier, controls sense data latch and generates a DLL enable signal EN. The DLL enable signal EN is a signal for informing start and end of burst to the DLL circuit 6.

An address decoder 4 decodes the burst start address (address signal for starting burst reading) from the burst synchronous control circuit 3 and feeds the address to a memory array 5.

The DLL circuit 6 generates a DLL clock C3 having the almost same phase as the external clock C1 and feeds the clock to the clock driver 7. The DLL circuit 6 will be described later in detail.

The clock driver 7 buffers the internal clock C2 from the clock control circuit 2 and the DLL clock C3 from the DLL circuit 6 and feeds the clocks to the DOUT F/F 13.

The sense amplifier 8 starts sensing according to an address transition signal ATD from the burst synchronous control circuit 3.

A burst data latch/data selector 12 latches output data from the sense amplifier 8 through a sense amplifier latch circuit 9 according to a burst data latch signal from the burst synchronous control circuit 3 via a flip flop (F/F) 10. Furthermore, the burst data latch/data selector 12 sends the data read by the sense amplifier 8 to the DOUT F/F 13 according to the burst address (burst sequence address automatically generated in the burst synchronous control circuit 3) from the burst synchronous control circuit 3 via a flip flop (F/F) 11.

The DOUT F/F 13 latches final data output to a DOUT buffer 14.

Furthermore, the DOUT F/F 13 adjusts output timing when the DLL is used and is not used.

Next, operations of the semiconductor memory shown in FIG. 1 during non-use of the DLL circuit and use of the DLL circuit will be outlined. However, whether or not the DLL circuit is used in the synchronous burst operation is input by the user command.

<Non-use of DLL Circuit>

First, operations in the case of non-use of the DLL circuit 6 will be described.

When the clock control circuit 2 detects an falling edge of the chip enable signal CE# or the address effective signal ADV# and both the signals become effective, the clock control circuit 2 outputs the burst start signal ST. The burst synchronous control circuit 3 receives the burst start signal ST, generates the burst address and the burst data latch signal and performs the burst reading operation. At this time, since the DLL effective signal V1 is disabled, the DLL circuit 6 does not operate. The DOUT F/F 13 senses that the DLL effective signal V1 is disabled and using the internal clock C2, not the DLL clock C3, burst output data is sent to the DOUT buffer 14.

<Use of DLL Circuit>

Next, operations in the case of use of the DLL circuit 6 will be described.

When the clock control circuit 2 detects a falling edge of the chip enable signal CE# or the address effective signal ADV# and both the signals become effective, the clock control circuit 2 outputs the burst start signal ST. The burst synchronous control circuit 3 receives the burst start signal ST, generates the burst address and the burst data latch signal and performs the burst reading operation. At this time, the burst synchronous control circuit 3 automatically sets latency shorter than the clock latency set by the user according to the setting signal from the command decoder/command register 1 by 1 clock (clock latency automatic correction).

At the same time, the burst synchronous control circuit 3 senses that the DLL effective signal V1 is enabled and outputs the DLL enable signal EN to the DLL circuit 6. The DLL circuit 6 senses the DLL effective signal V1, the burst start signal ST and the DLL enable signal EN, starts the DLL operation and feeds the DLL clock C3 corrected to have the almost same phase as the external clock C1 to the DOUT F/F 13. The DOUT F/F 13 senses that the DLL effective signal V1 is enabled and using the DLL clock C3 instead of the internal clock C2, outputs burst output data to the DOUT buffer 14.

When a predetermined burst sequence is finished, the burst synchronous control circuit 3 makes the DLL enable signal EN disabled and the DLL circuit 6 which receives the signal finishes the DLL operation.

The above-mentioned semiconductor memory in FIG. 1 has a function of switching between use of DLL and non-use of DLL for the following reason. A DLL basic operation is to delay the internal clock C2 which is delayed from the external clock C1 until the next edge of the external clock C1 (the same phase). In this case, when clock frequency becomes lower, amount of delay applied to the internal clock C2 becomes larger, leading to an increase in the delay element prepared internally (increase in chip area). Thus, according to a user command, whether or not DLL is used can be selected so that DLL is not used at low frequencies where influence of delay in the internal clock C2 is small and DLL is used at high frequencies where influence of delay in the internal clock C2 is considerable. For example, the user can set whether or not a function of allowing the DLL circuit 6 not to activate at 100 MHz or less as the influence of delay in the internal clock is small and to activate at 100 MHz or more, using 100 MHz as a reference, (read configuration function) is used.

The clock latency automatic correction function is provided for the following reason. Since the DLL clock C3 is further delayed with respect to the internal clock C2, when timing of burst output data is adjusted in the DOUT F/F 13, latency by 1 clock is generated as compared to the case of non-use of the DLL circuit 6. For this reason, in the case of use of the DLL, in the burst synchronous control circuit 3, internal latency is made smaller than the user setting by 1 clock, thereby canceling the delay of 1 clock in the DOUT F/F 13 so that latency viewed from the outside may be equal to the user setting.

<<Configuration of DLL Circuit>>

Hereinafter, the DLL circuit in FIG. 1 will be described with reference to figures.

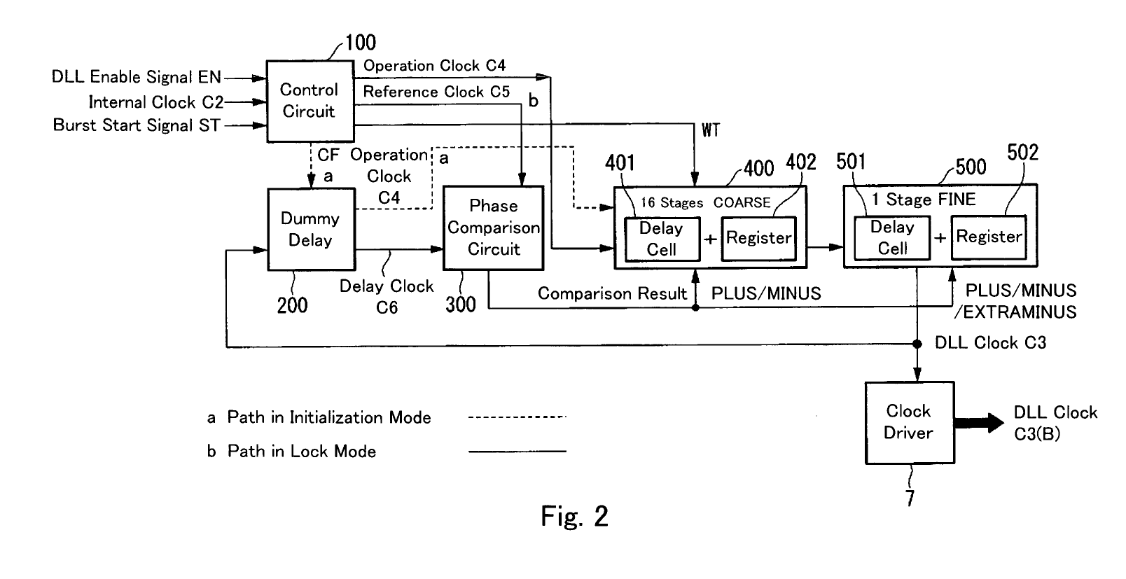

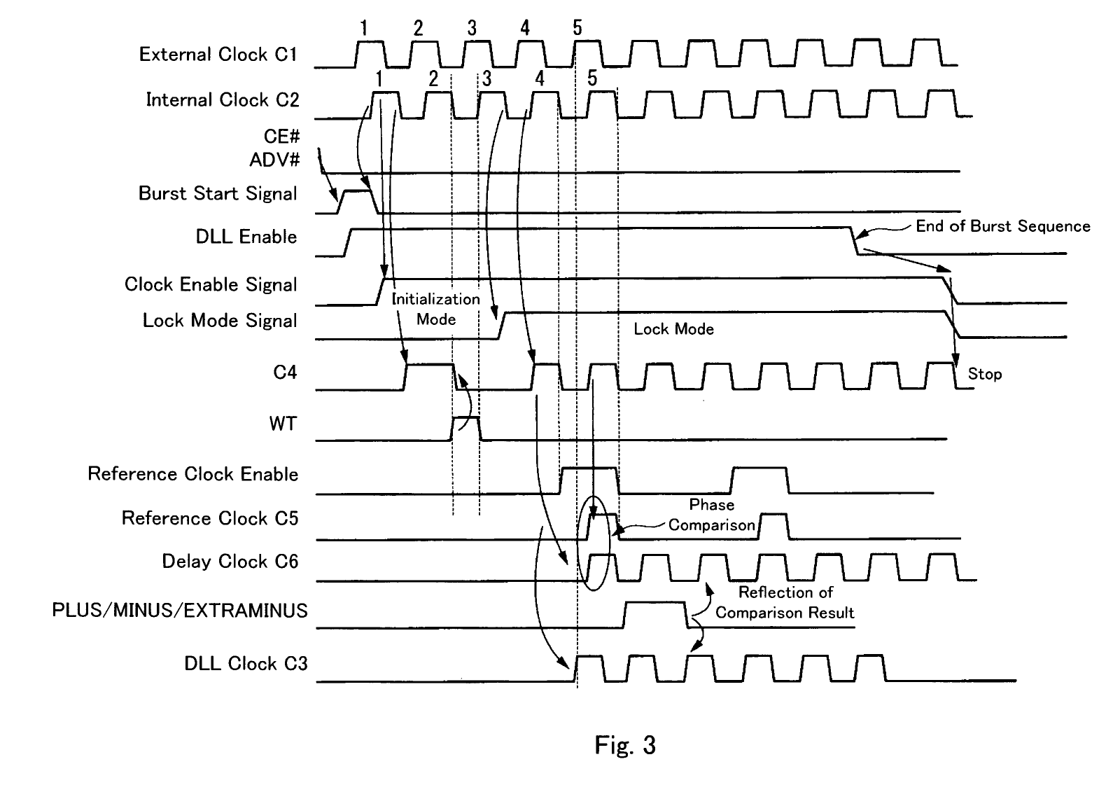

First, configuration and operations of the DLL circuit in this embodiment will be outlined with reference to FIG. 2 and FIG. 3. FIG. 2 is a schematic configuration view of the DLL circuit and FIG. 3 is a timing chart for describing the operations of the DLL circuit in FIG. 2. Detail of each component of the DLL circuit will be described later with reference to the other figures.

A control circuit 100 controls DLL operation clock generation (Timing generator), mode switching, stand-by and reset.

A dummy delay circuit 200 is a delay circuit for generating delay corresponding to an amount of internal delay of clock (Δt).

A phase comparison circuit 300 compares phase of two clocks (a reference clock C5 sent from the control circuit 100 and a delay clock C6 sent from the dummy delay circuit 200) and outputs a signal COAPLUS and a signal COAMINUS to a coarse delay circuit 400 and a signal FINEPLUS, a signal FINEMINUS and a signal EXTRAMINUS (a signal for bypassing the fine delay circuit 500) to a fine delay circuit 500.

The coarse delay circuit 400 is formed by serially connecting n (16 in this embodiment) coarse delay register units which each includes a coarse delay cell 401 and a coarse register 402 in an integral manner and performs coarse correction of delay amount (for example, 1 ns). Here, n is a value determined by the clock frequency, delay of the clock C2 and the like, and is referred to as “number of stages” in this description as appropriate.

The fine delay circuit 500 is formed of a fine delay cell 501 and serially connected n fine registers 502 and performs correction of delay amount (for example, 0.5 ns).

Unit delay amount of the fine delay circuit (for example, 0.5 ns) is larger than unit delay amount of the coarse delay circuit 400 (for example, 1 ns).

The clock driver 7 outputs the DLL clock C3 (B).

<<Operations of DLL Circuit>>

Hereinafter, operations of the DLL circuit in FIG. 2 will be described in order.

<Initialization Mode>

First, reset of the DLL circuit and operations in an operation circuit (in the initialization mode) will be described.

The clock control circuit 2 in FIG. 1 detects the falling edge of the chip enable signal CE# or the address effective signal ADV# and the burst start signal ST output when both the signals become effective is input to the control circuit 100 of the DLL circuit 6. Thereby, a sequential circuit in the DLL circuit 6, which is formed of a flip flop and a register, etc., is reset. After reset, in sync with the first falling edge of the internal clock C2, an operation clock CF is output to the dummy delay circuit 200 from the control circuit 100. The operation clock CF passes through the dummy delay circuit 200 to become an operation clock C4 and the operation clock C4 is input to the coarse delay circuit 400 (operation A101). This path is shown by a dotted line a in FIG. 2.

However, the operation clock CF is not a clock having periodicity but a signal of “H” level as an output to which an RS flip flop is set at the falling edge of the internal clock C2.

Generally, in a logic circuit, even the active logic is set as either “H” level or “L” level, the same circuit operation can be achieved. Therefore, also in this embodiment, using the logic value of the operation clock CF as “L”, the circuit can be achieved.

On the other hand, in the control circuit 100, in sync with the second falling edge of the internal clock C2, a write signal WT becomes “H” level. After that, in sync with the third rising edge of the internal clock, the write signal WT becomes “L” level and a synchronous pulse with a half clock is output to the coarse delay circuit 400 (operation A102).

In the control circuit 100, the above-mentioned RS flip flop is reset at “H” level of the write signal WT and the operation clock CF becomes “L” level. Accordingly, the operation clock C4 output from the dummy delay circuit 200 also becomes “L” level (operation A103).

In the coarse delay circuit 400, a clocked inverter included in each coarse delay cell 401 is disabled at “H” level of the write signal WT to stop output of the operation clock C4 (operation A104). Thereby, the operation clock C4 is transmitted only for 1 clock from the time when the operation clock CF becomes “H” level to the time when the write signal WT becomes “H” level.

At the time when the clocked inverter becomes disabled by “H” level of the write signal WT, the coarse register 402 of each stage of the coarse delay circuit 400 determines the stage that the operation clock C4 has reached referring to the logic (“H” level, “L” level) of the coarse delay cell 401 as a counterpart thereof. Then, the write signal WT becomes “L” level, the coarse register 402 of each stage writes the determination result. However, at the time when the clocked inverter becomes disabled and the operation clock C4 is stopped, “H” is written to only the coarse register 402 as a counterpart of the coarse delay cell 401 that the operation clock C4 reaches (the coarse register 402 as a counterpart of the rearmost one of the coarse delay cells 401 that the operation clock C4 reaches) (operation A105).

Thus, the initialization mode is finished. Through the above-mentioned operations, setting of “dummy delay by the dummy delay circuit 200+coarse delay by the coarse delay circuit 400=external clock of 1 cycle” is finished. At this time, the DLL clock C3 is not output.

In the case where delay at the DQ buffer becomes large due to poor performance of the DQ buffer or the used frequency is high (that is, internal clock delay and DQ delay is increased), when the external clock and the DQ output cannot be synchronized only by canceling the internal clock delay (setup time cannot be ensured), delay of the DQ buffer can be also cancelled by configuring the circuit so as to determine whether or not the relationship “dummy delay by the dummy delay circuit 200+coarse delay by the coarse delay circuit 400+dummy delay corresponding to DQ buffer delay=external clock of 2 cycles” is met. Although this embodiment is not shown in the present invention, it can be easily realized by adding some logic circuits to the embodiment of the present invention.

As understood by the above-mentioned description, in the initialization mode, the coarse delay circuit 400 operates as the variable delay addition circuit in the initialization mode (in the initialization mode, the fine delay circuit 500 does not operate as the variable delay addition circuit) and also operates as a means for storing an initial value of the delay amount therein.

<Lock Mode (Initial Clock Output)>

Next, operations of the DLL circuit in a lock mode (initial clock output) will be described.

A half clock after the write signal WT becomes “L” level and writing to the coarse register 402 is finished at the operation A105, in sync with the third falling edge of the internal clock C2 in the control circuit 100, a lock mode signal M becomes “H” level. When the lock mode signal M becomes “H” level, the control circuit 100 switches the path of the operation clock C4 to a path shown by a solid line b in FIG. 2 (operation A201).

A half clock after the operation A201, the control circuit 100 generates a one-shot pulse at each clock in sync with the fourth and subsequent rising edges of the internal clock and outputs the pulse signal as the operation clock C4 to each coarse register 402 of the coarse delay circuit 400 (operation A202). The reason why the one-shot pulse is adopted without using the internal clock C2 is, in the configuration in which the number of stages of the coarse delay circuit 400 and the fine delay circuit 500 is switched during “L” level of the operation clock C4, a duty ratio of the internal clock C2 is varied and the period of “L” level of the operation clock C4 is made longer, thereby leaving a margin for the timing at switching.

The operation clock C4 generated at the operation A202 passes through the coarse delay cell 401 of the coarse delay circuit 400 and the fine delay cell 501 of the fine delay circuit 500 and becomes the DLL clock C3. The DLL clock C3 passes the clock driver 7 and becomes the DLL clock C3 (B) (operation A203). Although the fine delay circuit 500 is set as 0 stage by the reset operation at the time of start and remains unadjusted, as mentioned in the description of the initialization mode, correction is made with the accuracy of the coarse delay cell 401 of the coarse delay circuit 400. It is a practicable accuracy.

By the operations in this lock mode (initial clock output), the DLL clock C3 in sync with the rising edge of the internal clock C2 from the fourth clock of the internal clock C2 can be generated. That is, the DLL clock C3, the initial dock of which is the same phase as the fifth clock of the external clock C1, can be generated.

<Lock Mode (Lock-on Operation)>

Operations of the DLL circuit in a lock mode (lock-on operation) will be described.

One clock after the lock mode signal M becomes “H” level at the operation A201, the control circuit 100 outputs a reference clock enable signal RCEN once every 3 clocks from the fourth falling edge of the internal clock C2. The reference clock C5 which is a logical AND (AND) between the reference clock enable signal RCEN and the internal clock C2 is output to the phase comparison circuit 300 (operation A301). That is, the reference clock C5 is output once every 3 clocks from the fifth rising edge of the internal clock C2.

In consideration of the possibility that a series of operations of phase comparison and adjustment of the number of stages of the coarse delay circuit 400 and fine delay circuit 500 may not be finished within 1 cycle when the operation frequency is high, the reference clock C5 is output once every 3 clocks.

The phase comparison circuit 300 determines the phase of the delay clock CG is earlier or later than the reference clock C5. That is, it is determined whether or not the relationship “variable delay (coarse delay and fine delay)+dummy delay=1 cycle” as the basic lock condition of the DLL circuit is met (operation A302). The delay clock C6 is a signal delayed by allowing the operation clock C4 to pass through the coarse delay cell 401 of the coarse delay circuit 400, the fine delay cell 501 of the fine delay circuit 500 and the dummy delay circuit 200 in this order.

The first operation clock C4 after transition to the lock mode is output from the fourth rising edge of the internal clock C2 (refer to the above-mentioned operation A202). After the operation clock C4 passes through the coarse delay cell 401 of the coarse delay circuit 400, the fine delay cell 501 of the fine delay circuit 500 and the dummy delay circuit 200 in this order, the delay clock C6 becomes a signal delayed by almost 1 cycle. This is due to that delay is set with the accuracy of the coarse delay circuit 400 in the initialization mode.

On the contrary, the reference clock C5 is output from the fifth clock of the internal clock C2.

Thus, the phase comparison circuit 300 determines whether or not the relationship “variable delay (coarse delay and fine delay)+dummy delay=1 cycle” as the basic lock condition of the DLL circuit is met.

In the case where delay at the DQ buffer becomes large due to poor performance of the DQ buffer or the used frequency is high (that is, internal clock delay and DQ delay is increased), when the external clock and the DQ output cannot be synchronized only by canceling the internal clock delay (setup time cannot be ensured), delay of the DQ buffer can be also cancelled by configuring the circuit so as to determine whether or not the relationship “variable delay (coarse delay and fine delay)+dummy delay+dummy delay corresponding to DQ buffer delay=2 cycles” is met. Although this embodiment is not shown in the present invention, it can be easily realized by adding some logic circuits to the embodiment of the present invention.

Based on the determination result at the operation A302, the phase circuit 300 outputs the signals (the signal COAPLUS, the signal COAMINUS, the signal FINEPLUS, the signal FINEMINUS and the signal EXTRAMINUS) (operation A303).

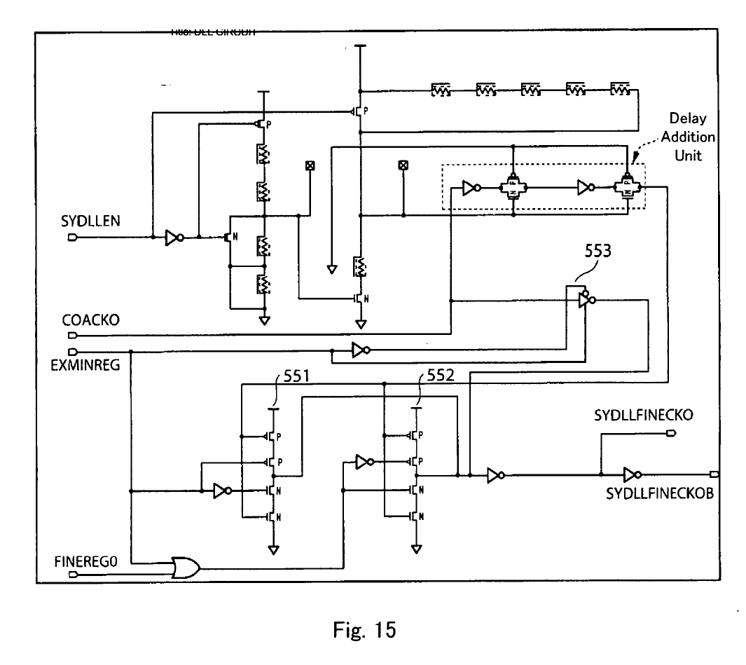

The coarse delay circuit 400 and the fine delay circuit 500 receive the output signals from the phase comparison circuit 300 (the signal COAPLUS, the signal COAMINUS, the signal FINEPLUS and the signal FINEMINUS) and adjust the number of stages, or the fine delay circuit 500 receives the output signal from the phase comparison circuit 300 (the signal EXTRAMINUS) and bypasses the fine delay cell 501 (operation A304). The bypass operation is performed to address the case where the phase of the delay clock C6 is too slow in spite that both the number of stages of the coarse delay circuit 400 and the number of stages of the fine delay circuit 500 are 0 stage (minimum setting). That is, when the phase the delay clock C6 to which a predetermined threshold value (in the case where the numbers of stages of the coarse delay circuit 400 and the fine delay circuit 500 are set to be minimum, the sum of the delay amount added by these circuits and the delay amount added by the dummy delay circuit 200) is added to the internal clock C2 is behind the reference clock C5, by bypassing the delay addition unit in the fine delay circuit 500 (refer to FIG. 15), delay is not added by the fine delay circuit 500.

In the coarse delay circuit 400 and the fine delay circuit 500, when no output signal is output from the phase comparison circuit 300, the relationship “variable delay+dummy delay=1 cycle” is met and thus, the coarse delay circuit 400 and the fine delay circuit 500 do not operate (lock-on state)(operation A305).

Even after lock-on is realized, phase comparison is carried out once every three clocks and each time the delay value varies due to change in the clock cycle, power supply voltage and environmental temperature, the coarse delay circuit 400 and the fine delay circuit 500 correct the phase by increasing or decreasing the number of stages (operation A306).

As understood by the description of the above-mentioned lock mode (initial clock output, lock-on operation) and the description that the unit delay amount of the coarse delay circuit 400 is larger than the unit delay amount of the fine delay circuit 500, in the lock mode, the coarse delay circuit 400 operates as a coarse variable delay addition circuit having coarse unit delay amount, and the fine delay circuit 500 has fine delay amount and thereby operates as a fine variable delay addition circuit which adds delay amount complementing the unit delay amount of the coarse delay circuit 400.

<Burst Terminating Operation>

Operations of the DLL circuit in burst termination will be described.

The DLL circuit 6 receives the falling edge of the DLL enable signal EN and terminates the DLL operation (operation A401). In the operation of overall burst synchronous reading, due to so-called pipeline processing, the DLL clock C3 needs to be output during 2 cycles since receipt of the DLL enable signal EN of “L” level from the burst synchronous control circuit 3 (burst termination). For this reason, a shift register is provided in the control circuit 100 to determine the timing when 2 clocks pass.

Although the DLL enable signal EN of “H” level is input to the DLL circuit 6 at burst start, the sequential circuit (sequence circuit) in the DLL circuit 6 does not use the “H” level and only uses the “H” level as a condition for termination of burst sequence. Burst start is carried out according to the burst start signal ST.

Hereinafter, each part of the DLL circuit will be described with reference to figures.

<Control Circuit>

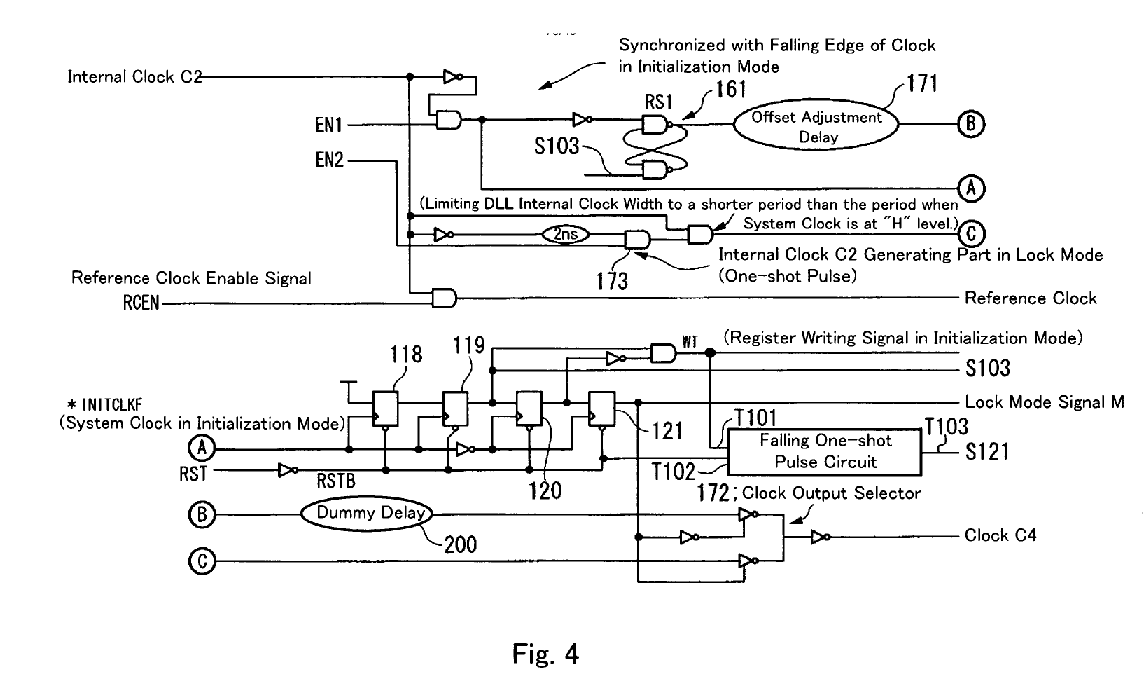

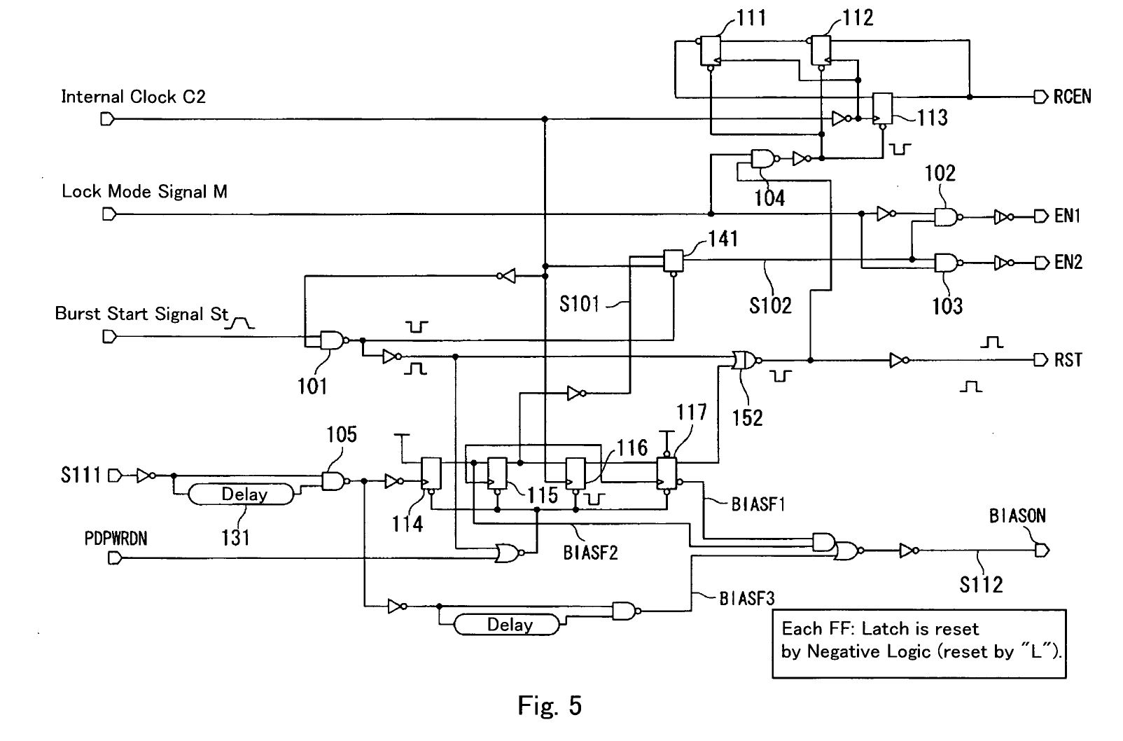

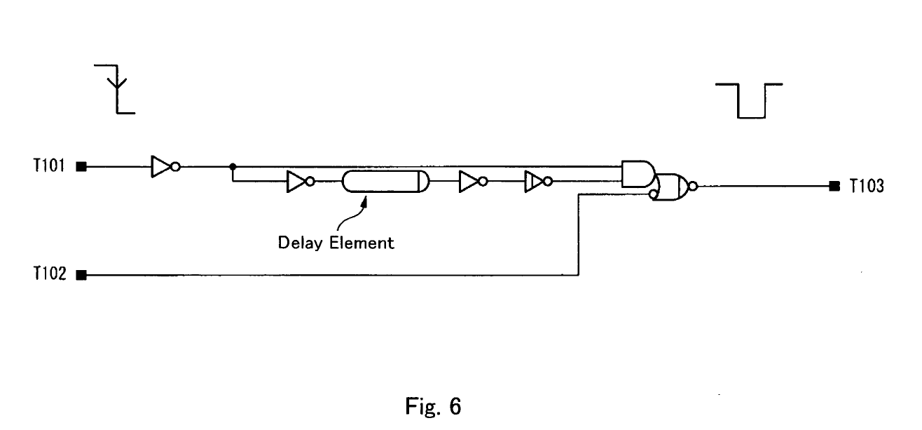

Operations of the control circuit will be described with reference to FIG. 4 to FIG. 6. FIG. 4 and FIG. 5 is a circuit diagram showing configuration of the control circuit in FIG. 2. FIG. 6 is a circuit diagram showing configuration of a falling one-shot pulse circuit in FIG. 4.

<Reset Operation>

First, a reset operation of the control circuit will be described. As described above, the burst start signal ST is a signal which becomes “H” level at a falling edge of the chip enable signal CE or the address effective signal ADV# which is input to the clock control circuit 2 in FIG. 1 and becomes “L” level at the first rising edge of the internal clock C2 (refer to FIG. 3).

The clock control circuit 2 feeds the burst start signal ST to flip flops 111 to 117 via an NAND circuit 101 to reset the flip flops 111 to 117 (operation B101). At the same time, The clock control circuit 2 outputs a reset signal RST to the other circuits (the phase comparison circuit 300, the coarse delay circuit 400 and the fine delay circuit 500) via an NOR circuit 152 (operation B102). When the burst start signal ST is greatly delayed on the chip and fed to the DLL circuit 6, timing of reset cancellation (burst start signal becomes “L” level) is delayed, thereby delaying start of internal operations. To prevent this, the NAND circuit 101 is used to force the burst start signal ST (of “H” level) to become “L” level at the first rising edge of the internal clock C2.

<Clock Enable Operation>

Next, a clock enable operation of the control circuit will be described.

After the above-mentioned reset operation, an inversion signal (signal S101) of the output of the flip flop 115 is “H” level. After that, at the first “H” level of the clock C2, an output (signal S102) of the half latch 141 becomes “H” level (operation B201).

The signal S102 and an inversion signal of the lock mode signal M are input to the NAND circuit 102, the lock mode signal M as an output of the flip flop 121 is “L” level immediately after reset and the inversion signal is “H” level. Thus, after reset, at the first “H” level of the internal clock C2, a clock enable signal EN1 in the initialization mode becomes “H” level (initialization mode start) (operation B202).

Then, when the lock mode signal M becomes “H” level (refer to FIG. 3), the clock enable signal EN1 becomes “L” level (disabled) and at the same time, the clock enable signal EN2 in the lock mode becomes “H” level via the NAND circuit 103 (lock mode start) (operation B203).

Even after reset by the burst start signal ST, by the NAND circuit 104, the flip flops 111 to 113 continues to be in a reset state in the period during which the lock mode signal M is “L” level (initialization mode). When the lock mode signal M becomes “H” level and is put into the lock mode, the reset state of the flip flops 111 to 113 is released and the flip flops 111 to 113 starts operation in sync with the falling edge of the internal clock C2 and generates the reference clock enable signal RCEN once every 3 clocks of the internal clock C2 (operation B204).

<Initialization Mode>

Operations of the control circuit in the initialization mode will be described.

At the operation B202, the clock enable signal EN1 becomes “H” level and the internal clock C2 becomes “L” level. As a result, an RS latch 161 is set and an output thereof becomes “H” level. The clock of “H” level passes through an offset adjustment delay 171 and the dummy delay 200 and becomes the operation clock C4 via a clock output selector 172 (operation B301). The offset adjustment delay 171 is provided for the following reason. Only the coarse delay circuit 400 determines the value of the variable delay in the initialization mode, while both the coarse delay circuit 400 and the fine delay circuit 500 determines the value of the variable delay in the lock mode. Thus, by passage through the offset adjustment delay 171 in the initialization mode, the difference between the value of the variable delay determined only by the coarse delay circuit 400 in the initialization mode and the value of the variable delay determined by the coarse delay circuit 400 and the fine delay circuit 500 in the lock mode can be cancelled.

Generally, in the logic circuit, even when the active logic is set at the “H” level or the “L” level, the same circuit operation can be realized. Therefore, also in this embodiment, the circuit can be realized setting the logic value of the operation clock C4 as “L”.

After 1 clock from setting, the RS latch 161 is reset by the output of the flip flop 119 (signal S103) (operation B302). That is, in the initialization mode, the operation clock C4 becomes a pulse having a width of 1 cycle.

At the same time, the write signal WT having a width of 1 clock is output to the coarse delay circuit 400 (operation B303). At the rising edge of the write signal WT, the number of stages of the coarse delay circuit 400 is determined and at the falling edge of the write signal WT, the determination result is written to the coarse register 402 of the coarse delay circuit 400.

<Lock Mode>

Operations of the control circuit in the lock mode will be described. The initialization mode is terminated by the write signal WT and after a half clock, the lock mode signal M becomes “H” level and thus, the initialization mode is shifted to the lock mode. Since the lock mode signal M becomes “H” level, the output of a one-shot pulse generation circuit 173 becomes the operation clock C4 via the clock output selector 172 (operation B401).

<BIAS ON Operation>

Operations of the control circuit in BIAS ON will be described. The coarse delay circuit 400 and the fine delay circuit 500 employ a circuit for reducing variations of the delay value due to power supply voltage. A circuit for applying BIAS to the transistor is also provided. Since this circuit generates a DC current from VCC to VSS in operation, to prevent useless power consumption, the circuit needs to be turned on only during DLL operation. For this reason, a sequence circuit for generating BIAS is provided in the control circuit.

When the signal 111 becomes “H” level, a nodal point BIASF3 rapidly becomes “H” level. Thus, the signal S112 at the nodal point BIASON also rapidly becomes “H” level, thereby turning on a bias generation circuit (operation B501).

When the signal 111 becomes “L” level, the nodal point BIASF3 becomes “L” level. However, by the operation of a shift register formed of the flip flops 114 to 117 during 3 clocks of the internal clock C2, both of nodal points BIASF1, BIASF2 become “H” level and the signal S112 at the nodal point BIASON also outputs “H” level during 3 clocks of the internal clock C2 (operation B502). That is, the signal S112 at the nodal point BIASON becomes “H” level at the rising edge of the signal S111 and becomes “L” level after 3 clocks from the falling edge. The reason why the signal is kept at “H” level during 3 clocks from the falling edge is that the operation clock C4 must be output twice even after the falling edge of the signal S111 in the specification of DLL and thus, allowance for one output is given.

<Burst Termination>

Operations of the control circuit in the burst termination will be described.

When the signal S111 becomes “L” level, the clock input of the flip flop 114 becomes “H” level and the output of the flip flop 114 becomes “H” level (the input of the flip flop 115 is “H” level) (operation B601). In the case where noise of “L” level occurs in the signal 111 for any reason, the delay 131 and the NAND circuit 105 mask the noise, thereby preventing the DLL circuit from improperly stopping.

At the rising edge of the internal clock C2 after the input of the flip flop 115 becomes “H”, the output of the flip flop 115 becomes “H” level and the signal S101 is reversed by the inverter to become “L” level (operation B602). Since the internal clock C2 is “H” level in this period, the signal S102 becomes “L” level via the half latch 141 and the clock enable signal EN2 becomes “L” level to stop the output of the operation clock C4 (operation B603). That is, the operations from the falling edge of the signal S111 to this point are performed in 2 cycles, the operation clock C4 is output for 2 clocks from the falling edge of the signal S111 and then output of the operation clock C4 is stopped.

The flip flops 116, 117 takes the timing of 2 cycles, the output of the flip flop 117 becomes “H” level and the flip flops 111 to 113 are put into a reset state via the NOR circuit 152. At the same time, the reset signal RST becomes “H” level and the flip flops 118 to 121, the dummy delay circuit 200, the phase comparison circuit 300, the coarse delay circuit 400 and the fine delay circuit 500 in the DLL are reset (operation B604).

<Falling One-Shot Pulse Generating Operation>

A falling one-shot pulse generating operation of a falling one-shot circuit in the control circuit in FIG. 6 will be described. The coarse delay circuit 400 has a latch (formed of a clocked inverter) for determining at which stage the clock C4 reaches in the initialization mode therein and at the time of termination of the initialization mode, the latch needs to be reset.

When the write signal WT is input to an input terminal T101 and the write signal WT falls, the input of the input terminal T101 falls, an one-shot pulse of “L” level is generated in an output terminal T103 and this pulse becomes a signal S121 (operation B701). At the time of start and end of the DLL, an inversion signal RSTB of the reset signal RST is input and when the inversion signal is “L” level, the output of the output terminal T103 becomes “L” level (operation B702).

<Dummy Delay Circuit>

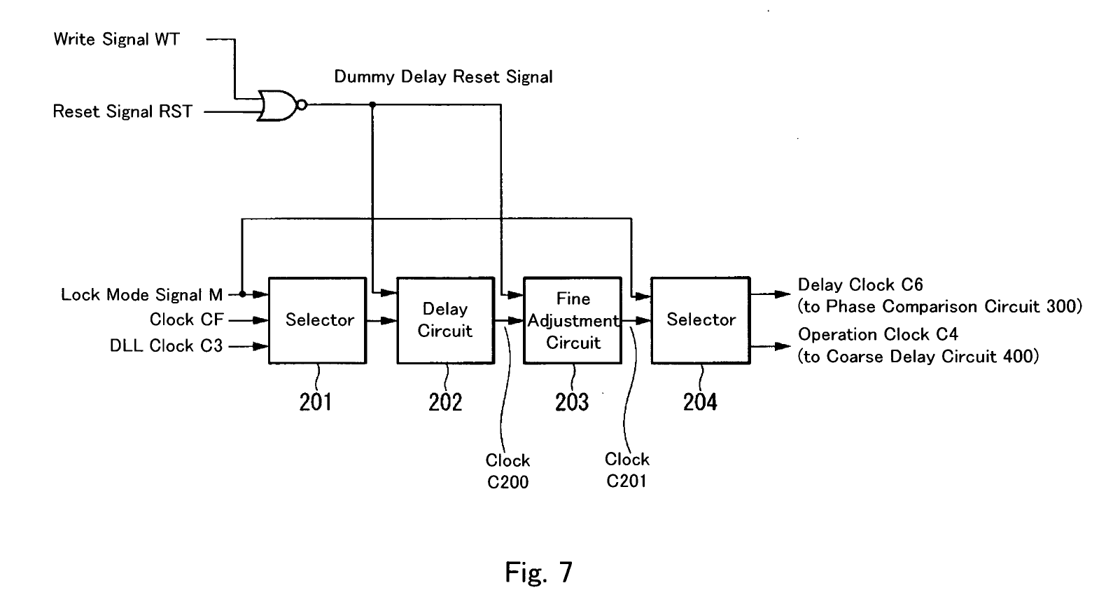

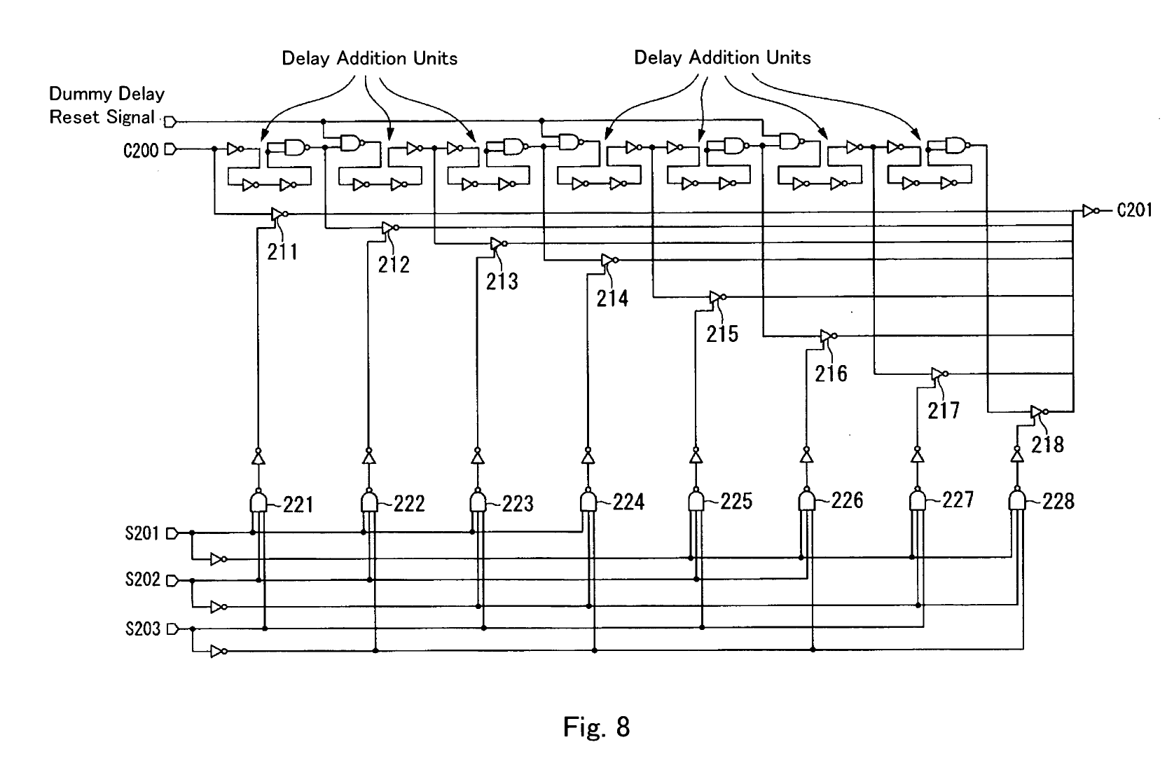

Next, configuration and operations of the dummy delay circuit will be described with reference to FIG. 7 and FIG. 8. FIG. 7 is a circuit diagram showing configuration of the dummy delay circuit in FIG. 2. FIG. 8 is a view showing configuration of a fine adjustment circuit in FIG. 7.

When the reset signal RST or the write signal WT becomes “H”, the dummy delay reset signal becomes “L” and a clock path of the delay circuit 202 and the fine adjustment circuit 203 is reset. The reset signal RST is an internal circuit reset signal at the start of burst and burst termination.

When the number of stages of the coarse delay circuit 400 is determined in the initialization mode, the write signal WT becomes “H” and the clock path is reset once for the subsequent lock mode.

When the lock mode signal is “L” level (in the initialization mode), the selector 201 feeds the operation clock CF fed from the control circuit 100 in FIG. 2 to a delay circuit 202. When the lock mode signal is “H” level (in the lock mode), the DLL clock C3 input from the fine delay circuit 500 in FIG. 2 is fed to the delay circuit 202.

The delay circuit 202 is formed of a set of four inverter chains of multiple stages and outputs a clock C200.

The fine adjustment circuit 203 adjusts the delay amount based on the input to the fine adjustment circuit 203 (signals S201, S202, S203 of “H” or “L”). FIG. 8 is an example of the circuit. In only one of the NAND circuits 221 to 228, all inputs become “H” level and the output becomes “L” level and reversed by the inverter to become “H” level. Among the clocked inverters 211 to 218, only the clocked inverter as a counterpart of the NAND circuit having all inputs of “H” level is opened. The clock C200 becomes a clock C201 through delay addition units (0 to 7) and the opened clocked inverter and is output to a selector 204. Thus, in the fine adjustment circuit 203, the number of delay addition units through which the clock passes from input to output can be varied from 0 to 7.

Inputs S201, S202 and S203 to the fine adjustment circuit are signals output from a storage means prepared in the same chip and when a nonvolatile memory cell, for example, is used as the storage means, fine adjustment can be performed by writing a value from the outside at shipment and when a volatile memory cell such as SRAM or a register formed of a flip flop and the like is used, fine adjustment can be performed by writing a value from the outside during usage.

When the clock mode signal is “L” level (in the initialization mode), the selector 204 feeds the input to the coarse delay circuit 400. When the lock mode signal is “H” level (in the lock mode), the selector 204 outputs the input to the phase adjustment circuit 300.

<Phase Comparison Circuit>

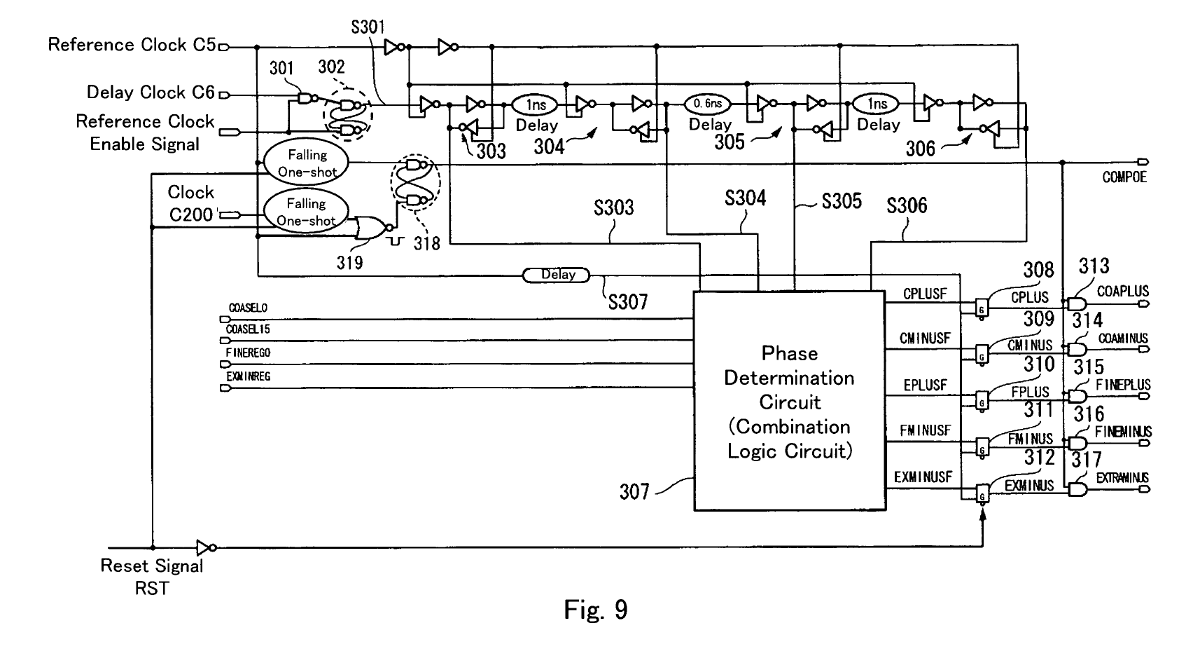

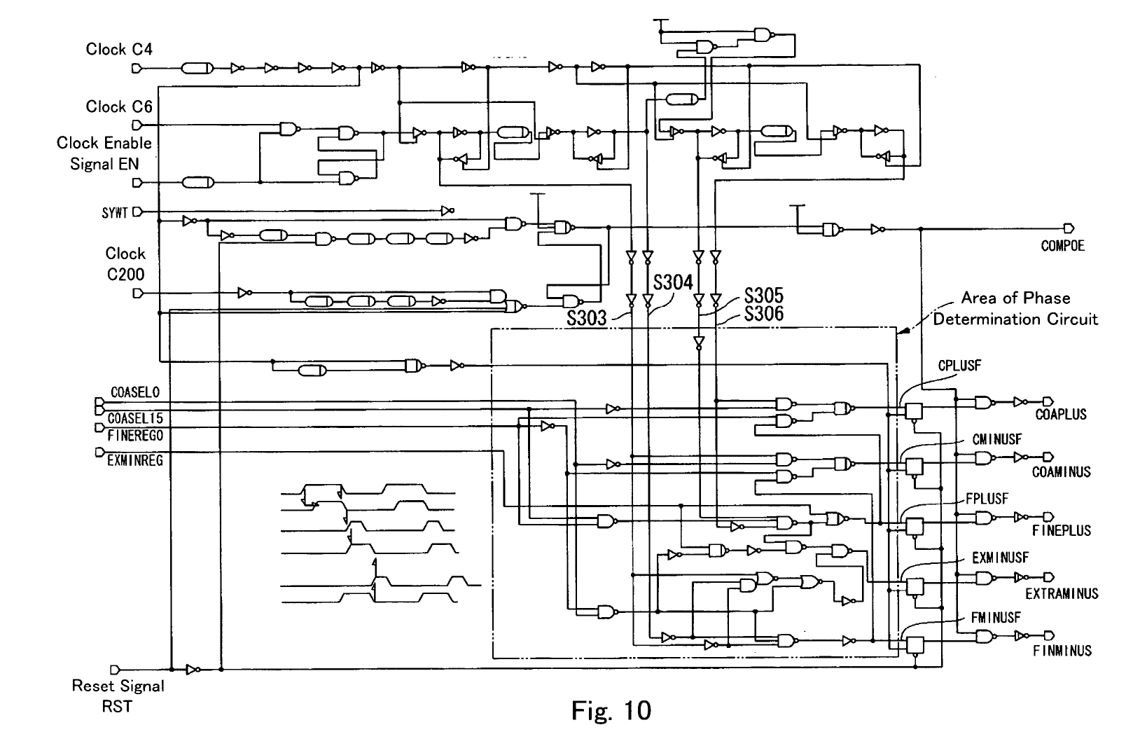

Next, operations of the phase comparison circuit will be described with reference to FIG. 9 and FIG. 10. FIG. 9 is a circuit diagram showing configuration of the phase comparison circuit in FIG. 2. FIG. 10 is an example of the phase comparison circuit in FIG. 9. Although the reset signal RST in FIG. 9 is input to the latches of flip flops 308 to 312, they are omitted in FIG. 9.

The phase comparison circuit 300 compares the phase of the reference clock C5 with the phase of the delay clock C6. Since the delay clock C6 is a clock after the internal clock C2 passes through the coarse delay circuit 400, the fine delay circuit 500 and the dummy delay circuit, phase comparison between the reference clock C5 and the delay clock C6 means determining whether or not the lock on condition of the DLL circuit 6 “dummy delay+variable delay (coarse delay and fine delay)=1 cycle” is met. The reference clock C5 is a signal output from the control circuit 100 once every 3 clocks of the internal clock C2.

The reset signal RST resets the latch circuits 308 to 312, an RS flip flop circuit 302 and an RS flip flop circuit 318.

The delay clock C6 to be compared is input to the RS flip flop 302 via the NAND circuit 301. The reference clock enable signal RCEN is input to the other input of the NAND circuit 301 (operation C11). The NAND circuit 301 serves to perform phase comparison only once every 3 clocks of the internal clock C2 and prevent input of the delay clock C6 in the other clocks.

When the reference clock enable signal RCEN is enabled (“H” level), the delay clock C6 is input to the RS flip flop 302 and the output of the RS flip flop 302 (signal S301) becomes “H” level (operation C102).

Since the operation clock C4 which is an original clock of the delay clock C6 is a one-shot pulse generated by the AND circuit 173 in the control circuit 100, the period of “H” level is short. Thus, the RS flip flop 302 is used to compensate the period of “H” level, thereby preventing wrong determination in phase comparison.

The reference clock enable signal RCEN becomes “L” level and thus, the RS flip flop 302 is reset and the signal S301 becomes “L” level (operation C103).

While the reference clock C5 is “L” level (the rising edge of the reference clock C5 has not been reached), the latch circuits 303 to 306 are in an opened state and “H” level of the output of the RS flip flop 302 (signal S301) is sequentially transmitted thereto (operation C104).

When the reference clock C5 becomes “H” level, the latch circuits 303 to 306 are closed (latched), and at this time, transmission of the output of the RS flip flop 302 is stopped (operation C105).

Values (signals S303 to S306) of the nodal points N303 to 306 of the latch circuits 303 to 306 are input to a phase determination circuit 307 (operation C106). The signal of each nodal point has the following meaning. “S303=1” means that the coarse delay circuit 400 is delayed by 1 or more stages. “S304=0” means that the fine delay circuit 500 is delayed by about 1 stage. “S305=0” means that the fine delay circuit 500 is advanced by about 1 stage. “S306=1” means that the coarse delay circuit 400 is advanced by 1 or more stages.

The phase determination circuit 307 is formed of a general combination logic circuit (refer to FIG. 10) and outputs signals CPLUSF, CMINUSF for controlling the coarse delay circuit 400 and signals FPLUSF, FMINUSF and EXMINUSF for controlling the fine delay circuit 500 by combination of the outputs (signals S303 to S306) of the latch circuits 303 to 306, signals COASEL0, COASEL15 from the coarse delay circuit 400, and signals FINEREG0, EXMINREG from the fine delay circuit (operation C107). The phase determination circuit (combination logic circuit) 307 functions as a logic circuit which detects that both the delay amount of the coarse delay circuit 400 and the fine delay circuit 500 is set to be minimum (the number of stages is 0) according to the delay amount setting signals output from the coarse delay circuit 400 and the fine delay circuit 500.

The logic of the phase determination circuit (combination circuit) (condition that each output signal becomes active “1”) is as follows.

The case of the signal CPLUSF (the number of stages of the coarse delay circuit 400+) is as follows.

In the case where the reference clock C5 reaches the nodal point N306 (signal S306=1) and the signal COASEL15 is 0 (the number of stages of the coarse delay circuit 400 is not 15), the signal FINEREG is 1 and the signal FPLUSF is 1 (carry from the fine delay circuit 500). The case of the signal CMINUSF (the number of stages of the coarse delay circuit 400−) is as follows. When the reference clock C5 doses not reach the nodal point N303 (signal S303=1) and the signal COASELO is 0 (the number of stages of the coarse delay circuit 400 is not 0), the signal FINEREG becomes 0 and the signal FMINUS becomes 1 (borrow from the fine delay circuit 500).

The case of the signal FPULSF (the number of stages of the fine delay circuit 500+) is as follows. When the reference clock C5 reaches the nodal point N305 (signal S305=0) and does not reach the nodal point N306 (signal S306=0), the signal FINEREG0 is 0 or the signal COASEL15 is 0 (carry is unnecessary or carry in the coarse delay circuit is possible) and the signal EXMINREG is 0.

The case of the signal FMINUSF (the number of stages of the fine delay circuit 500−) is as follows. When the reference clock C5 reaches the nodal point N303 (signal S303=0) and does not reach the nodal point N304 (signal S304=0), the signal FINEREG0 is 1 or the signal COASEL0 is 0 (borrow is unnecessary or borrow in the coarse delay circuit 400 is possible).

The case of the signal EXMINUSF is as follows. The signal COASEL0 is 0 and the signal FINEREG is 0 (both the coarse delay circuit and the fine delay circuit are 0 stage) and the reference clock C5 does not reach the nodal point N304 (signal S304=0). Once the signal EXMINREG becomes 1, the value is kept until the condition that the signal EXMINREG reaches the nodal point N305 (signal S305=0) and does not reach the nodal point N306 (signal S306=0) is met.

This indicates that the fine delay circuit 500 is advanced by 1 stage.

In the case where the reference clock C5 reaches the nodal point N304 (signal S304=1) and does not reach the nodal point N305 (signal S305=1), this case does not meet any one of the above-mentioned conditions and represents the lock state, the phase of the reference clock C5 corresponds to the phase of the delay clock C6 and there is no output from the phase determination circuit 307.

Since the phase determination circuit 307 is a combination circuit, the timing of final output for controlling the coarse delay circuit 400 and the fine delay circuit 500 needs to be taken. For this reason, the output of the phase determination circuit 307 is input to the latch circuits 308 to 312 in later stages (operation C108). Each of the latch circuits 308 to 312 takes in the output of the phase determination circuit 307 when the signal S307 which is delayed from the reference clock C5 is “H” level (operation C109). That is, the latch circuits 303 to 306 for phase comparison are closed when the reference clock C5 is “H” level and then, the latch circuits 308 to 312 take in the phase determination result by the phase determination circuit 307.

After that, when the reference clock C5 becomes “L” level and the delayed signal S307 becomes “L” level, the latch circuits 308 to 312 are closed (latch the phase determination result) (operation C110). AND circuits 313 to 317 are provided at later stages of the latch circuit 308 to 312 and the signals COAPLUS, COAMINUS, FINEPLUS, FINEMINUS and EXTRAMINUS are output according to a register control signal COMPOE (operation C111).

The above-mentioned register control circuit COMPOE is generated by the RS flip flop 318. The operation of the RS flip flop 318 is set at the falling of the reference clock C5 (COMPOE=“H”) and reset at the clock C200 (COMPOE=L). The clock C200 is a signal delayed by passage of the reference clock C5 through the coarse delay circuit 400. An NOR circuit 319 is used to reset the RS flip flop 318 when the reference clock C5 becomes “H”, that is, at the phase comparison start point.

<Coarse Delay Circuit>

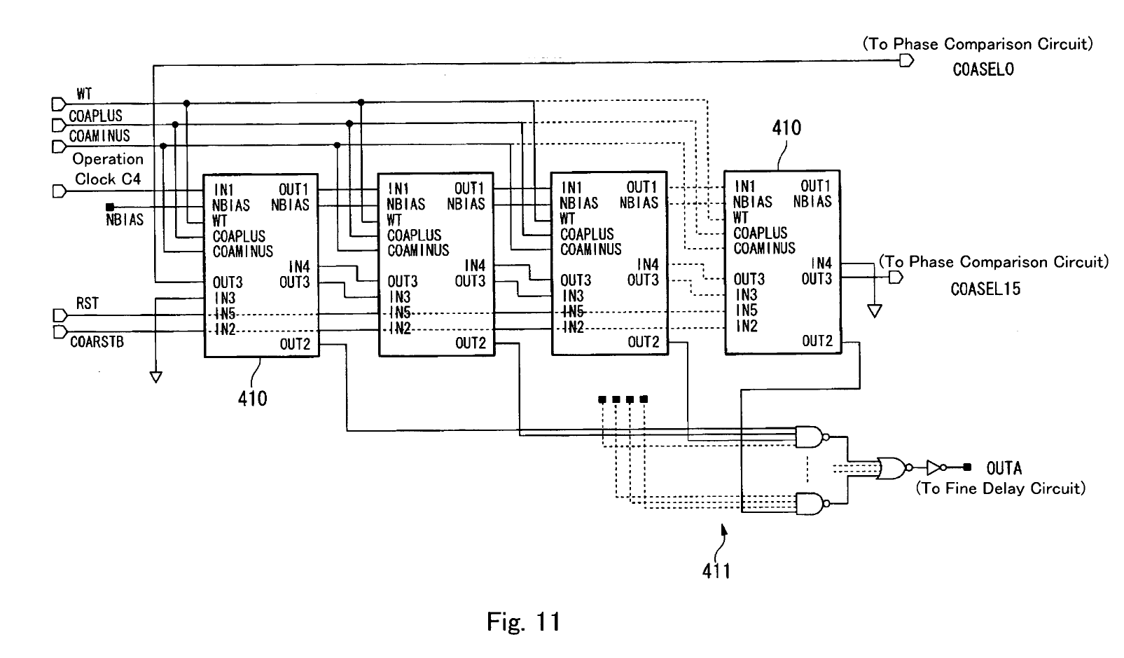

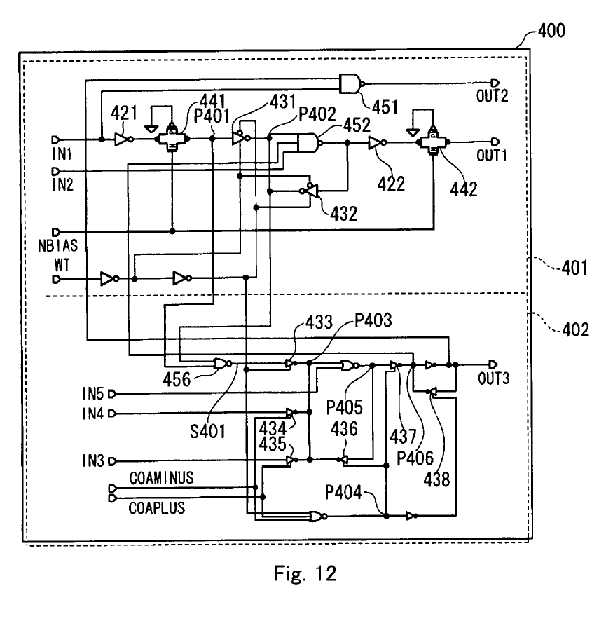

Next, configuration and operations of the coarse delay circuit will be described with reference to FIG. 11 and FIG. 12. FIG. 11 is a circuit diagram showing configuration of the coarse delay circuit in FIG. 2. FIG. 12 is a circuit diagram showing configuration of a coarse delay register circuit in FIG. 11.

The coarse delay circuit 400 is formed by serially connecting the n coarse delay register circuits 410 (16 in this embodiment) to each other, each having the coarse delay cell 401 and the coarse register 402 as a pair as described above.

“Initialization Mode” First, operations of the coarse delay circuit 400 in the initialization mode will be described.

The operation clock C4 is input to each coarse delay register circuit 410. First, the operation clock C4 input from the dummy delay circuit 200 is input to a terminal IN1 of the coarse delay register circuit 410 of the first stage and fed to the NAND circuit 451 and the inverter circuit 421 (operation D101). The other input of the NAND circuit 451 is reset by an output SYSEL of the coarse register 402 as a counterpart at the start of the DLL operation and becomes “L” level. Thus, the operation clock C4 is not transmitted to a terminal OUT2 (operation D102).

On the other hand, the clocked inverter 431 is controlled by the write signal WT supplied from the control circuit 100 and the write signal WT is “L” level and enabled. Referring to the timing chart in FIG. 3, as described above, since the write signal WT changes from “L” level to “H” level after 1 clock from the output of the operation clock CF (operation clock CF=“H”), the operation clock C4 is output to the terminal OUT1 via the inverter circuit 421, a transfer gate 441, the clocked inverter 431, an NAND circuit 452, an inverter circuit 422 and a transfer gate 442 in this period (operation D103). This path is a path for applying the coarse delay (1 stage).

The terminal OUT1 is connected to the terminal IN1 of the coarse delay register circuit 410 of the next stage, and thereby the output of a terminal OUT2 is sequentially transmitted to the coarse delay register circuit 410 of the next stage while the write signal WT is “L” level (operation D104).

When the write signal WT becomes “H” level after 1 clock from the output of the operation clock CF (refer to FIG. 3), the clocked inverter 431 is closed and the clocked inverter 432 is opened to latch the value of the nodal point P402 at that time (operation D105).

The output S401 of the NOR circuit 456 at that time becomes “H” level when both the nodal point P401 and the nodal point P402 are “L” level, and the output S401 becomes “L” level in the other period (operation D106).

That is, the condition that is the output S401 of the NOR circuit 456 becomes “H” level is that both the nodal point P401 and the nodal point P402 are “L” level. This condition means that “H” level of the operation clock C4 as an input from the terminal IN1 reaches the nodal point P401 and does not reach the nodal point P402.

It is apparent that only one of n coarse delay register circuits 410 meets the condition. The fact the clock reaches the nodal point P401 means that the clock reaches the nodal point P402 of the previous coarse delay register circuit 410 and unless the clock reaches the nodal point P402, the clock cannot reach the nodal point P401 of the next coarse delay register circuit 410.

The operation D106 determines what number of coarse delay register circuits 410 the operation clock C4 can reach during 1 clock from start of the output of the operation clock CF. That is, since operation clock C4 passes through the dummy delay circuit 200 in the initialization mode, it can be said that the operation D106 determines that the condition “dummy delay+variable delay (only coarse delay by the coarse delay circuit 400)=1 cycle” is met.

Since the write signal WT is “H” level, the clocked inverter 433 is opened and an input IN5 is a reset signal of “L” at this time, and thus the value of the output (signal S405) is transmitted to the nodal point P405 (operation D107). In the coarse delay register circuit 410 which meets the above-mentioned condition, the value of the nodal point P403 is “H” level and in the coarse delay register circuit 410 which does not meet the above-mentioned condition, the value is “L” level.

At this time, the signal COAPLUS and the signal COAMINUS output from the phase comparison circuit 300 in the lock mode is “L” level and the clocked inverters 434 and 435 are closed. The value of the nodal point P404 becomes “L” level of the reversed write signal WT and the clocked inverters 436 and 437 are closed. Furthermore, the value of the nodal point P404 is reversed to become “H” level, the clocked inverter 438 is opened, the value of the nodal point P405 before it changes is reversed and the reversed values is latched (operation D108). That is, though the value of the nodal point P405 varies when the write signal WT is “H” level (only one of the coarse delay register circuits is “H”), the output of the terminal OUT3 does not change.

A half clock after the write signal WT becomes “H” level, the write signal WT becomes “L” level (refer to FIG. 3). Thus, since the clocked inverter 433 is closed and the value of the nodal point P404 becomes “H” level, the clocked inverter 436 is opened and the value of the nodal point P405 is latched (operation D109). That is, “H” is written to the coarse register 402 of any one of the coarse delay circuits 410.

At the same time, since the value of the nodal point P404 becomes “H” level, the clocked inverter 437 is opened and then reversed to become “L” level. Thus, the clocked inverter 438 is closed and the value written to the coarse register 402 is output to the terminal OUT3 (operation D110).

By inputting a pulse of “L” level from the control circuit 100 to the terminal IN2 immediately after the write signal WT becomes “L” level, the latch formed of the NAND circuit 452 and the clocked inverter 432 is reset (operation D111).

“Lock Mode (Initial Clock Output)”

Next, operations of the coarse delay circuit in the lock mode (initial clock output) will be described.

Through the operations in the above-mentioned initialization mode, “H” is written to only one of the coarse registers 402 of the coarse delay register circuits 410.

The operation clock C4 is input to the terminal IN1 of the coarse delay cell 401 of the first coarse delay register circuit 410. At this time, if “H” is written to the coarse register 402 as a counterpart, the output of the terminal OUT3 is “H” and the output of the terminal OUT2 becomes the reversed value of the operation clock C4 via the NAND circuit 451 (operation D201). The output from the terminal OUT2 reaches an output OUTA of the coarse delay circuit 400 via a clock composition unit 411 and is output to the fine delay circuit 500 (operation D202). Since the value of the terminal OUTA becomes a reversed logic of the value of the terminal OUT2, the value becomes a positive logic with respect to the operation clock C4.

On the other hand, since the value of the nodal point P406 is “L” level, the input (operation clock C4) to the terminal IN1 is prohibited by the NAND circuit 452 and is not transmitted to the terminal OUT1. Since the terminal OUT1 is the input of the terminal IN1 of the next stage, the operation clock C4 is not transmitted to the next stage. It does not pass through the part which applies delay (operation D203).

In the coarse delay register circuit 410 in which “L” is written to the coarse register 402, transmission from the terminal IN1 to the terminal OUT1 is performed and the operation clock C4 is transmitted to the next stage.

For example, when “H” is written to the coarse register 410 of the first coarse delay register circuit 410, the operation clock C4 passes the path of the NAND circuit 451 without passing through any delay element and this is called 0 stage. When “H” is written in the 16th register, this is called 15 stage. The coarse delay circuit 400 can set one among 16 delay values.

“Lock Mode (Lock-on Operation)”

Operations of the coarse delay circuit in the lock mode (lock-on operation) will be described.

In the coarse delay circuit 400, the signal COAPLUS and the signal COAMINUS which correspond to the phase comparison result are input from the phase comparison circuit 300 (operation D301). The signal COAPLUS and the signal COAMINUS are pulses of “H” level having width of 1 clock.

When the signal COAPLUS is input from the phase comparison circuit 300, the signal COAPLUS is “H” level and the clocked inverter 435 is opened. The input of the terminal IN3 is the output value (value written to the coarse register 402) of the terminal OUT3 of the coarse delay register circuit 410 previous to the noted coarse delay register circuit 410. Accordingly, only when the signal COAPLUS is “H” level and the value written to the coarse register 402 of the previous coarse delay register circuit 410 is “H”, the value of the nodal point P405 becomes “H” level (operation D302).

After 1 clock, when the signal COAPLUS becomes “L” level, the clocked inverter 436 is opened, the value “H” of the nodal point P405 is latched and “H” is written to the coarse register 402 (operation D303).

In the coarse delay register circuit 410 in which “H” is written to the coarse register 402, the following processing is performed. When the signal COAPLUS is “H” level, the clocked inverter 435 is opened. Since “L” is written to the coarse register 402 of the previous coarse delay register circuit 410, the value of the nodal point P405 becomes “L” level. When the signal COAPLUS becomes “L” level, the clocked inverter 436 is opened, the value “L” of the nodal point P405 is latched and “L” is written to the coarse register 402.

For example, if “H” is written to the coarse register 402 of the fifth coarse delay register circuit 410, “H” is written to the coarse register 402 of the sixth coarse delay register circuit 410 according to the signal COAPLUS and “L” is written to the coarse register 402 of the fifth coarse delay register circuit 410. As a result, the number of stages of the coarse delay circuit 410 is increased from 4 to 5. The value written to the coarse registers 402 of the other coarse delay register circuits 410 remains unchanged (“L”).

When the signal COAMINUS is input from the phase comparison circuit 300, the signal COAMINUS is “H” level and the clocked inverter 434 is opened. The input of the terminal IN4 is an output value (the value written to the coarse register 402) of the terminal OUT of the coarse delay register circuit 410 following the noted coarse delay register circuit 410. Accordingly, only when the signal COAMINUS is “H” level and the value written to the coarse register 402 of the following coarse delay register circuit 410 is “H”, the value of the nodal point P405 becomes “H” level (operation D304).

After 1 clock, when the signal COAMINUS becomes “L” level, the clocked inverter 436 is opened, the value “H” of the nodal point P405 is latched and “H” is written to the coarse register 402 (operation D305).

In the coarse delay register circuit 410 in which “H” is written to the coarse register 402, the following processing is performed. When the signal COAMINUS is “H” level, the clocked inverter 434 is opened. Since “L” is written to the coarse register 402 of the following coarse delay register circuit 410, the value of the nodal point P405 becomes “L” level. When the signal COAMINUS becomes “L” level, the clocked inverter 436 is opened, the value “L” of the nodal point P405 is latched and “L” is written to the coarse register 402.

For example, if “H” is written to the coarse register 402 of the fifth coarse delay register circuit 410, “H” is written to the coarse register 402 of the fourth coarse delay register circuit 410 according to the signal COAMINUS and “L” is written to the coarse register 402 of the fifth coarse delay register circuit 410. As a result, the number of stages of the coarse delay circuit 410 is decreased from 4 to 3. The value written to the coarse registers 402 of the other coarse delay register circuits 410 remains unchanged (“L”).

In the case where both the signal COAPLUS and the signal COAMINUS are not input, the coarse register 402 of the coarse delay circuit 400 does not operated.

At burst start and burst termination, the coarse register 402 of each coarse delay register circuit 410 is reset by inputting the reset signal to the terminal IN5 (writing “L”).

As understood from the above-mentioned description, by reflecting the phase comparison result in the phase comparison circuit 300, the number of stages of the coarse delay circuit can be increased or decreased.

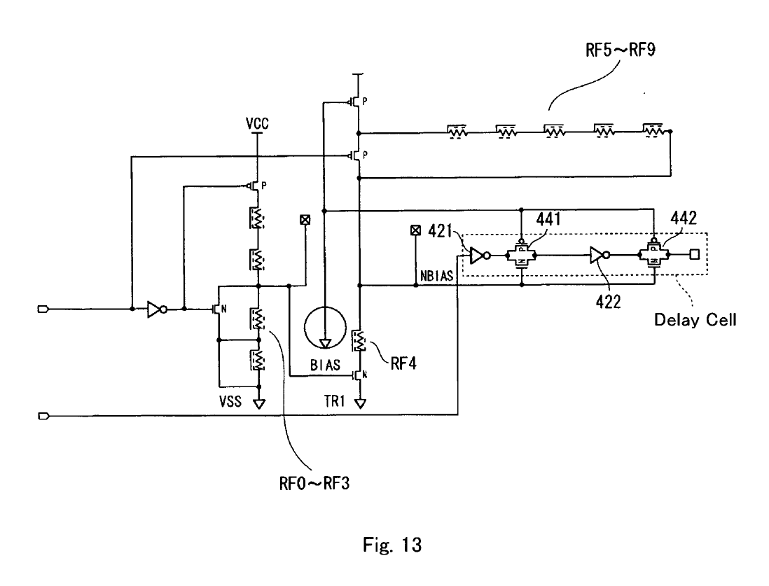

FIG. 13 shows an example of the delay cell for reducing variations in delay time with respect to voltage. The delay element (delay cell) in FIG. 11 is formed of the inverter 421, the transfer gate 441, the inverter 422 and the transfer gate 442. A BIAS nodal point divided by resistances RF0 to RF3 depends on variations in power supply voltage VCC. An NBIAS nodal point divided by the resistances RF5 to RF9, an N channel transistor TR1 and the resistance RF4 is adjusted so as to have inverse characteristics to BIAS voltage as gate voltage of the transistor TR1. In other words, As the power supply voltage is higher, the voltage of the BIAS nodal point is higher and On-resistance of the transistor TR1 is decreased. Thus, the voltage of the NBIAS nodal point becomes lower.

Since the gate voltage of the N channel transistor forming a transfer gate of the transfer gates 441, 442 becomes lower as the voltage of the NBIAS nodal point becomes lower, the resistance value of the transfer gates 441, 442 becomes larger, leading to an increase in delay of the whole transfer gate. That is, when the power supply voltage becomes high, the delay value of the transfer gate becomes large, thereby enabling the transfer gate to have inverse characteristics to general delay characteristics. In general inverters 421, 422, since the delay value becomes smaller as the power supply voltage becomes higher, by combining the inverters 421, 422 with the transfer gates 441, 442, even when the power supply voltage is high, variations in the delay values can be minimized. Furthermore, although the delay value of the inverters 421, 422 becomes larger as the power supply voltage becomes lower, the delay value of the transfer gate 441, 442 becomes smaller. Thus, by combining them, even when the power supply voltage is low, variations in the delay values can be minimized. That is, even when the power supply voltage becomes higher or lower, variations in the delay values can be minimized.

<Fine Delay Circuit>

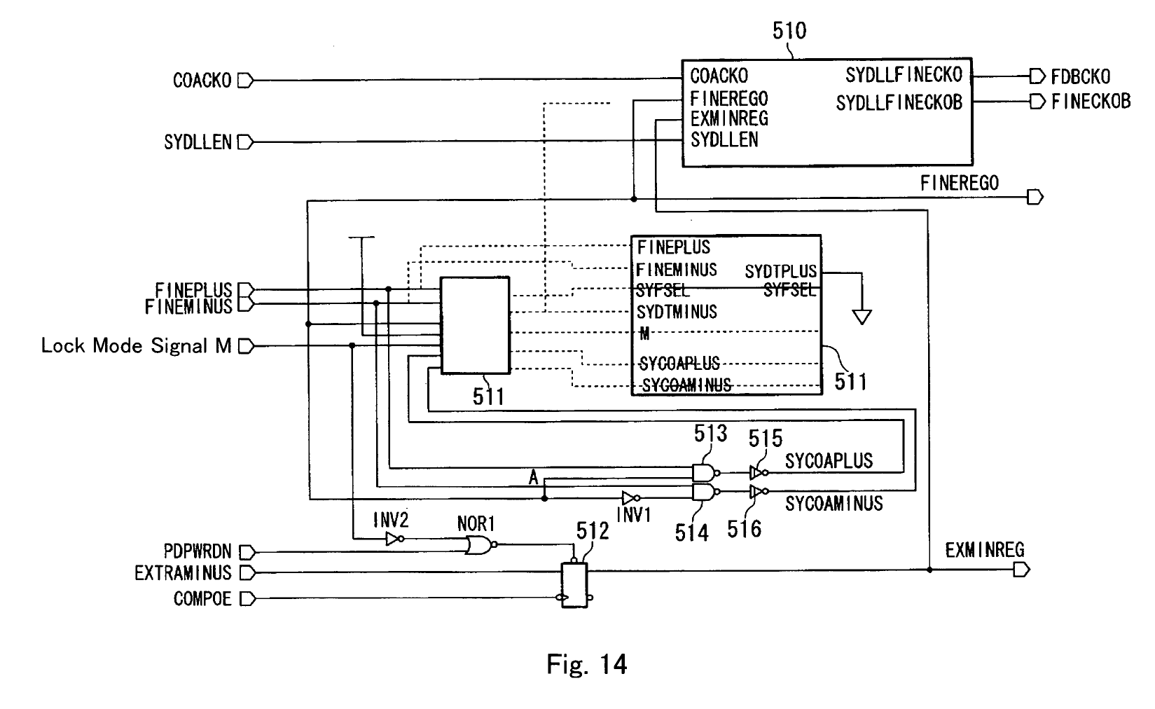

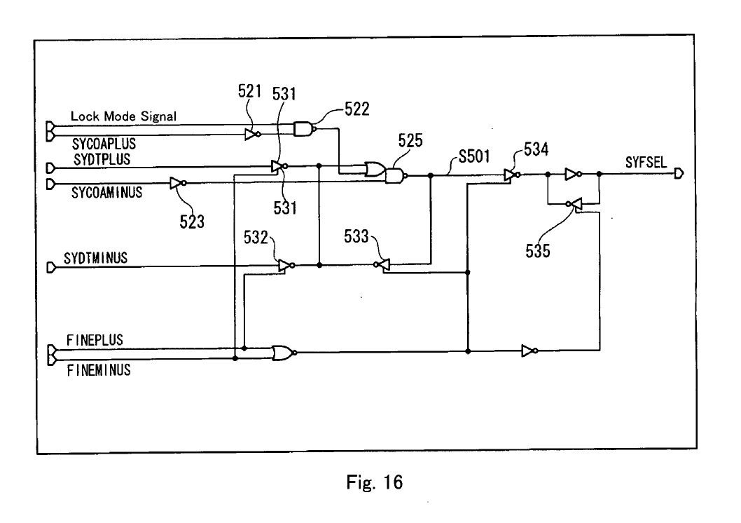

Configuration and operations of the fine delay circuit will be described with reference to FIGS. 14 to 16. FIG. 14 is a circuit diagram showing configuration of a fine delay circuit in FIG. 2. FIG. 15 is a circuit diagram showing configuration of the fine delay circuit in FIG. 14, and FIG. 16 is a circuit diagram showing configuration of a fine register circuit in FIG. 14. COACKO in the figures corresponds to OUTA in FIG. 11. Like the delay cell in FIG. 13, the delay addition unit in FIG. 15 is formed of an inverter and a circuit having inverse characteristics to the inverter circuit in terms of power supply voltage, thereby minimizing variations in the delay amount due to variations in power supply voltage.

The fine delay circuit 500 has a fine delay circuit 510, a fine register circuit 511 and an extraminus register circuit (a register which stores a signal EXTRAMINUS output from the phase comparison circuit 300 as a signal for bypassing the fine delay circuit 500) 512 formed of a flip flop. N fine register circuits 511 are prepared and adjust the fine delay value at (n+1) stages in cooperation with the fine delay circuit 510. In this embodiment, only one fine register circuit 511 is provided and the fine delay value has two grades called as 0 stage, 1 stage. Note that there is no state where “L” is written to all stages of the coarse registers 402 of the coarse delay circuits 400, while there is a state where “L” is written to all stages in the fine register circuit and thus, (n+1) stages is generated.

A combination logic circuit formed of inverters 515, 516 and NAND circuits 513, 514 is a control circuit for performing carry and borrow in cooperation with the coarse register 402 of the coarse delay circuit 400.

<Operations in the Case where Carry, Borrow is not Performed>

First, operations in the case where carry, borrow is not performed will be described. The signals COAPLUS, COAMINUS are “L” level. The signals FINEPLUS, FINEMINUS are “H” pulses having width of 1 clock.

The fine register circuit 511 is reset by “L” level of the lock mode signal M (in the initialization mode) (operation E101). Since the signals FINEPLUS, FINEMINUS from the phase comparison circuit 300 in the lock mode are “L” level, clocked inverters 531, 532 are closed, a clocked inverter 533 is opened and at that time, the output (signal 501) of an ONAND circuit 525 becomes “L”.

After that, when the mode is shifted to the lock mode and “H” level of the signal FINEPLUS is input from the phase comparison circuit 300, the clocked inverter 532 is opened. Since SYDTMINUS of the lowest fine register is fixed at VCC, the output (signal S501) of the ONAND 525 becomes “H” level (operation E102). After 1 clock of the internal clock, the signal FINEPLUS becomes “L” level, the clocked inverter 532 is closed, the clocked inverters 533, 534 are opened and “H” is written to the lowest register (operation E103).

Then, when “H” level of the signal FINEPLUS is input, since SYDTMINUS of the lowest fine register is fixed at VCC, “H” is written to the fine register to which “H” is previously written and the one previous to the fine register (operation E104).

When the signal FINEMINUS is input (“H” level) in the case where “H” is written to any stage, since DTPLUS of the highest fine register is fixed at VSS, “L” is sequentially written from the higher register (operation E105). That is, when “H” level of the signal FINEMINUS is input, the clocked inverter 531 is opened, and since the highest SYDTPLUS is fixed at VSS, the output (signal S501) of the ONAND circuit 525 becomes “L” level. Then, after 1 clock, when the signal FINEMINUS becomes “L” level, the clocked inverter 531 is closed, the clocked inverters 533, 534 are opened and “L” is written.

<Operations of Carry, Borrow>

Operations of carry, borrow of the fine delay circuit will be described. In the case where “L” is written to the lowest fine register (“L” is written to all of the fine registers), when “H” level of the signal FINEMINUS signal is input, the signal SYCOAMINUS becomes “H” level. In each fine register, the output (signal S501) of the ONAND circuit 525 becomes “H” level. After that, the signal FINEMINUS becomes “L” level and “H” is written to the fine registers of all stages (operation E201). At this time, “H” level of the signal COAMINUS is input from the phase comparison circuit 300 to the coarse register 402 of the coarse delay circuit 400 and the number of stages is decreased by 1. In this manner, the coarse delay circuit 400 and the fine delay circuit 500 cooperate with each other to perform borrow operation.

In the case where “H” is written to the highest fine register (“H” is written to all of the fine registers), when “H” level of the signal FINEPLUS is input, the signal SYCOAPLUS becomes “H” level. In each fine register, the output (signal S501) of the ONAND circuit 525 becomes “L” level. After that, the signal FINEPLUS becomes “L” level and “L” is written to the fine registers of all stages (operation E301). At this time, “H” level of the signal COAPLUS is input from the phase comparison circuit 300 to the coarse register 402 of the coarse delay circuit 400 and the number of stages is increased by 1. In this manner, the coarse delay circuit 400 and the fine delay circuit 500 cooperate with each other to perform carry operation.

The output of each fine register circuit 511 is input to the fine delay circuit 510 and the clocked inverters 551, 552 which are connected to each other in parallel are enabled, thereby changing drive capacity and increasing or decreasing the delay value (operation E401).

The EXTRAMINUS register 512 is set by “L” level of the lock mode signal (in the initialization mode) and outputs a signal EXMINREG of “H” level. When the signal EXMINREG is “H” level, the clocked inverter 553 of the fine delay circuit 510 is opened, the relay addition unit is bypassed (operation E501) and FDBCKO (corresponding to the DLL clock C3 in FIG. 2) is output from SYDLLFINECKO to the dummy delay circuit 200. Furthermore, FINECKOB (corresponding to DLL clock C3 in FIG. 2) is output from SYDLLFINECKOB to the clock driver 7. After that, by the value of the signal EXTRAMINUS from the phase comparison circuit 300 and a falling edge of COMPOE (“H” pulse having width of 1 clock), the value of the signal EXMINREG is changed (operation E502). The clocked inverter 553 functions as a switching means for bypassing the delay addition unit in the fine delay circuit.

In the DLL circuit of the present invention, since the delay amount of the delay element varies depending on variations in power supply, attention needs to be given to variations in power supply voltage or power supply noise.

It is preferred that the DLL circuit of the present invention is disposed as near to a power supply PAD as possible. This is to prevent influence of variations in power supply voltage or power supply noise as well as to avoid influence of voltage decrease due to power supply wiring resistance.

To rapid variations of power supply voltage due to power supply noise and the like, it is effective to separate power supply wiring supplied to DLL from power supply wiring of the other circuits and provide a noise filter (a low-pass filter and the like) formed of, for example, CR at the power supply line.

As described above, although the preferred embodiment of the present invention has been described, the present invention is not limited to the above-mentioned embodiment and can be variously changed in design as long as it is described in claims.

### INDUSTRIAL APPLICABILITY

The DLL circuit according to the present invention can be applied to a DLL (Delay Locked Loop) circuit which is useful in a flash memory and used in a semiconductor memory such as a flash memory.

1. A DLL circuit having a dummy delay corresponding to delay between an internal clock delay and an external clock, a variable delay addition circuit having a coarse delay circuit and a fine delay circuit for adjusting delay amount according to a delay amount adjustment signal, and a phase comparison circuit for comparing a phase of the internal clock with a phase of a delay clock input via the variable delay addition circuit and the dummy delay and outputting the delay amount adjustment signal to the variable delay addition circuit, the DLL circuit comprising:
a means for inputting a first signal set at a logic “1” during 1 clock cycle of the internal clock to the variable delay addition circuit via the dummy delay as an initialization mode at a start of burst;
a means for detecting duration time of the logic “1” of the first signal input by the variable delay addition circuit through the dummy delay until the end of the 1 clock cycle of the internal clock and setting an initial value of delay amount of the variable delay addition circuit by setting the delay amount of the coarse delay circuit in the variable delay addition circuit based on the duration time as the initialization mode at the start of burst; and
a clock output means for generating an output clock that synchronizes with the external clock one clock cycle behind with the internal clock delayed by the coarse delay circuit and the fine delay circuit in the variable delay addition circuit and with the delay amount of the coarse delay circuit and the fine delay circuit in the variable delay addition circuit corrected according to the delay amount adjustment signal output from the phase comparison circuit as a lock mode after initial setting of the delay amount in the variable delay addition circuit.

2. A DLL circuit having a dummy delay corresponding to delay between an internal clock delay and an external clock, a variable delay addition circuit having a coarse delay circuit and a fine delay circuit, for adjusting delay amount according to a delay amount adjustment signal, and a phase comparison circuit for comparing a phase of the internal clock with a phase of a delay clock input via the variable delay addition circuit and the dummy delay and outputting the delay amount adjustment signal to the variable delay addition circuit, the DLL circuit comprising:
a means for inputting a first signal set at a logic “1” during 1 clock cycle of the internal clock to the variable delay addition circuit via the dummy delay as an initialization mode at a start of burst;
a means for detecting duration time of the logic “1” of the first signal input by the variable delay addition circuit through the dummy delay until the end of the 1 clock cycle of the internal clock and setting an initial value of delay amount of the variable delay addition circuit by setting the delay amount of the coarse delay circuit in the variable delay addition circuit based on the duration time as the initialization mode at the start of burst; and
a clock output means for generating an output clock that synchronizes with the external clock one clock cycle behind with the internal clock delayed by the coarse delay circuit and the fine delay circuit in the variable delay addition circuit and with the delay amount of the coarse delay circuit and the fine delay circuit in the variable delay addition circuit corrected according to the delay amount adjustment signal output from the phase comparison circuit as a lock mode after initial setting of the delay amount in the variable delay addition circuit, wherein
the coarse delay circuit operates as the variable delay addition circuit and a means for storing setting of the initial value in the initialization mode and operates as a coarse variable delay addition circuit having coarse unit delay amount in the lock mode, and
the fine delay circuit operates as a fine variable delay addition circuit adding delay amount for complementing the unit delay amount of the coarse delay circuit by having fine unit delay amount in the lock mode.

3. The DLL circuit according to claims 1 or 2 comprising a means for preventing delay from being added to the delay clock in the fine delay circuit in the variable delay circuit, when the phase of the delay clock obtained by adding predetermined threshold delay amount to the internal clock lags behind the internal clock, as a determination result of the phase comparison circuit in the lock mode.

4. The DLL circuit according to claims 1 or 2, wherein a delay element in the coarse delay circuit and the fine delay circuit which form the variable delay addition circuit is formed of an inverter circuit and a circuit having inverse characteristics to the inverter circuit in terms of power supply voltage.

5. A variable delay addition circuit forming a DLL circuit having a dummy delay corresponding to delay between an internal clock delay and an external clock, a variable delay addition circuit including a coarse delay circuit and a fine delay circuit, for adjusting delay amount according to a delay amount adjustment signal, and a phase comparison circuit for comparing a phase of the internal clock with a phase of a delay clock input via the variable delay addition circuit and the dummy delay, outputting the delay amount adjustment signal to the variable delay addition circuit, and having a logic circuit for detecting that the delay amount of the coarse delay circuit and the fine delay circuit is set to be minimum by the delay amount setting signal output from the coarse delay circuit and the fine delay circuit, wherein
the fine delay circuit includes a register that stores a signal output from the phase comparison circuit for bypassing the fine delay circuit, and a switching means for bypassing the delay addition unit in the fine delay circuit in response to the output of the register, and
the delay addition unit in the fine delay circuit is bypassed and the delay is prevented from being added in the fine delay circuit, when the delay amounts of both the coarse delay circuit and the fine delay circuit are set to be minimum and the phase of the delay clock lags behind the internal clock.
